(19) United States
(12) Patent Application Publication
(10) Pub. No.: US 2026/0290479 A1
(43) Pub. Date: Sep. 24, 2026

(54) FLEXIBLE CLOCK ALLOCATION FOR PROGRAM-VERIFY OPERATIONS

(71) Applicant: Sandisk Technologies, Inc., Milpitas, CA (US)

(72) Inventors: Chengqing Hu, Milpitas, CA (US); Dong-il Moon, San Jose, MI (US); Henry Chin, Fremont, CA (US); Wanfang Tsai, Palo Alto, CA (US)

(21) Appl. No.: 19/088,136

(22) Filed: Mar. 24, 2025

(51) Int. Cl. G11C 16/34; G11C 16/12; G11C 16/32

(52) U.S. Cl. CPC G11C 16/3459; G11C 16/12; G11C 16/32; G11C 16/3404

(57) ABSTRACT

The present disclosure provides for performing program-verify operations of a memory device. The memory device includes a memory block that includes a plurality of memory cells that are connected to a plurality of data word lines. The memory device also includes circuitry that is configured to conduct a first operation of the program-verify operation to verify a threshold voltage of one or more memory cells connected to a selected data word line of the plurality of data word lines is above a verify low voltage. The circuitry is also configured to, during the first operation, apply a programming voltage to the selected data word line. In some examples, the first operation can be a lockout low bit-scan.

### BACKGROUND

### 1. Field

The present disclosure is related generally to the operation of NAND memory devices and, more particularly, to techniques verify flexibly allocating sub-clocks for program verify of memory cell programming.

### 2. Related Art

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. Programming the memory cells of a word line to retain data typically occurs in a plurality of program loops, each of which includes the application of a programming pulse to a control gate of the word line and, optionally, a verify operation to sense the threshold voltages of the memory cells being programmed. Each program loop may also include a pre-charge operation prior to the programming pulse to pre-charge a plurality of channels containing memory cells to be programmed.

### SUMMARY

An aspect of the present disclosure is related to a method of performing a program-verify operation of a memory device. The method includes the step of preparing a memory block that includes a plurality of memory cells that are connected to a plurality of data word lines. The method also includes performing a first operation of the program-verify operation to verify a threshold voltage of one or more memory cells connected to a selected data word line of the plurality of data word lines is above a verify low voltage. The method further includes, during the first operation, applying a programming voltage to the selected data word line.

According to another aspect of the present disclosure, the first operation can be lockout low bit-scan.

According to yet another aspect of the present disclosure, performing the first operation can further include steps of: applying a verify low voltage to the selected data word lines, and verifying the programming of the one or more memory cells connected to the selected data word line based on the verify low voltage.

According to still another aspect of the present disclosure, the method can include the steps of performing the first operation after ramping down a voltage on a gate of a bit line clamp (BLC) transistor connected to a bit line coupled to the one or more memory cells, and applying a VBLC_QPW to the gate of the BLC transistor after the first operation is completed.

According to another aspect of the present disclosure, a time window allocated to the first operation can be defined based on setting a time at which the VBLC_QPW is applied to the gate of the BLC transistor.

According to another aspect of the present disclosure, the first operation can be started based on setting a time at which the VBLC_QPW is applied to the gate of the BLC transistor.

According to yet another aspect of the present disclosure, performing a first operation can comprise determining the threshold voltage of the one or more memory cells is above the verify low voltage, and applying a quick pass write voltage to a bit line coupled to the one or more memory cells based on the determination.

According to another aspect of the present disclosure, the quick pass write voltage can be applied to the bit line coupled to the one or more memory cells after the programming voltage is applied to the selected data word line.

According to another aspect of the present disclosure, the method can also include the steps of applying a boosting voltage to one or more of unselected data word lines and the selected data word line, and starting the first operation after applying the boosting voltage.

According to still another aspect of the present disclosure, the method can include the steps of, prior to performing the first operation, performing a second operation to verify a threshold voltage of at least one memory cell connected to the selected data word line of the plurality of data word lines is above a verify high voltage, and applying a program inhibit voltage to a bit line coupled to the at least one memory cell.

Another aspect of the present disclosure is related to a memory device. The memory device includes a memory block that includes a plurality of memory cells that are arranged in a plurality of data word lines. The memory device also includes circuitry that is configured to conduct a first operation of a program-verify operation to verify a threshold voltage of one or more memory cells connected to a selected data word line of the plurality of data word lines is above a verify low voltage and, during the first operation, apply a programming voltage to the selected data word line.

According to another aspect of the present disclosure, the performing the first operation can further include steps of applying a verify compare voltage to the first set of data word lines, and verifying the programming of one or more memory cells connected to a selected data word line based on the verify compare voltage.

According to still another aspect of the present disclosure, the circuitry can further be configured to perform the first operation after ramping down a voltage on a gate of a bit line clamp (BLC) transistor connected to a bit line coupled to the one or more memory cells, and apply a VBLC_QPW to the gate of the BLC transistor after the first operation is completed.

According to another aspect of the present disclosure, a time window allocated to the first operation can be defined based on setting a time at which the VBLC_QPW is applied to the gate of the BLC transistor.

According to yet another aspect of the present disclosure, the first operation can be started based on setting a time at which the VBLC_QPW is applied to the gate of the BLC transistor.

According to still another aspect of the present disclosure, the performing the first operation can comprise determining the threshold voltage of the one or more memory cells is above the verify low voltage, and applying a quick pass write voltage to a bit line coupled to the one or more memory cells based on the determination.

According to another aspect of the present disclosure, the quick pass write voltage can be applied to the bit line coupled to the one or more memory cells after the programming voltage is applied to the selected data word line.

According to still another aspect of the present disclosure, the circuitry can be further configured to, prior to performing the first operation, perform a second operation to verify a threshold voltage of at least one memory cell connected to the selected data word line of the plurality of data word lines is above a verify high voltage, and apply a program inhibit voltage to a bit line coupled to the at least one memory cell.

Another aspect of the present disclosure is related to an apparatus. The apparatus includes a memory block that includes a plurality of memory cells that are arranged in a plurality of word lines and in a plurality of bit lines. The bit lines include bit line claim (BLC) transistors. The apparatus also includes a controller that is configured to program one or more memory cells connected to a selected word line in a programming operation and allocate a portion of the programming operation to a first operation based on a setting that defines when a voltage is applied to the BLC transistors. The programming operation includes, during the program-verify operation, verifying a threshold voltage of one or more memory cells connected to a selected data word line of the plurality of data word lines is above a verify low voltage, and applying a programming voltage to the selected data word line.

According to another aspect of the present disclosure, the programming operation can further include performing the first operation after ramping down the voltage on the BLC transistors, and applying a VBLC_QPW to the BLC transistor after the first operation is completed.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope. The disclosure is described and explained with added specificity and detail through the use of the accompanying drawings in which:

FIG. 1A is a block diagram of an example memory device;

FIG. 1B is a block diagram of an example control circuit;

FIG. 1C is a block diagram illustrating that the memory device of FIG. 1A is configured to operate according to a pre-charge technique according to the present disclosure;

FIG. 2 depicts blocks of memory cells in an example two-dimensional configuration of the memory array of FIG. 1A;

FIG. 3A and FIG. 3B depict cross-sectional views of example floating gate memory cells in NAND strings;

FIG. 4A and FIG. 4B depict cross-sectional views of example charge-trapping memory cells in NAND strings;

FIG. 5 depicts an example block diagram of the sense block SB1 of FIG. 1;

FIG. 6A is a perspective view of a set of blocks in an example three-dimensional configuration of the memory array of FIG. 1;

FIG. 6B depicts an example cross-sectional view of a portion of one of the blocks of FIG. 6A;

FIG. 6C depicts a plot of memory hole diameter in the stack of FIG. 6B;

FIG. 6D depicts a close-up view of region 622 of the stack of FIG. 6B;

FIG. 7A depicts a top view of an example word line layer WL0 of the stack of FIG. 6B;

FIG. 7B depicts a top view of an example top dielectric layer DL116 of the stack of FIG. 6B;

FIG. 8 illustrates an example implementation of a sensing circuit in accordance with an embodiment of the present disclosure

FIG. 9 depicts a threshold voltage distribution of a page of memory cells programmed to one bit per memory cell (SLC);

FIG. 10 depicts a threshold voltage distribution of a page of memory cells programmed to three bits per memory cell (TLC);

FIG. 11 depicts a threshold voltage distribution of a page of memory cells programmed to four bits per memory cell (QLC);

FIG. 12 depicts a waveform of the voltages applied to a control gate of a selected word line during an exemplary programming operation;

FIG. 13 is a flow chart describing a process for programming an example memory block;

FIG. 14 depicts threshold voltage distributions of the memory cells of a data state line before and after programming using a Quick Pass Write (QPW) programming technique;

FIG. 15 illustrates an example of a method of programming using a QPW programming technique that includes multiple program-verify operations;

FIG. 16A is a signal diagram describing the behavior of various signals during an example program-verify operation;

FIG. 16B is a schematic block timing diagram of the various signals of FIG. 16A;

FIG. 17A is a signal diagram describing the behavior of various signals during an example of an early program-verify operation;

FIG. 17B is a schematic block timing diagram of the example of the various signals of FIG. 17A;

FIG. 18 is a graphical representation of a drain-side select gate voltage (VSGD) window loss;

FIG. 19 is a graphic representation of erased state distribution deformation;

FIG. 20 illustrates voltage waveforms applied to various components of a memory block during a program loop that includes a program-verify operation, a pre-charge operation, and programming;

FIG. 21 is a flow chart depicting the steps of programming the memory cells of a selected data word line according to an example embodiment of the present disclosure;

FIG. 22 depicts a schematic block diagram of timing allocated for at least one program-verify operation;

FIG. 23 illustrates voltages applied to various components of a memory block during an exemplary embodiment of a program loop with a delayed program-verify operation;

FIG. 24 depicts a schematic block diagram of the timing allocations for a delayed program-verify operation; and

FIG. 25 is a flow chart depicting the steps of programming the memory cells of a selected data word line according to an example embodiment of the present disclosure.

### DESCRIPTION OF THE ENABLING EMBODIMENTS

The present disclosure is related to pre-charge techniques for flexibly allocating portions of a programming loop for performing program-verify operations based on a portion allocated for slow programming of memory cells. According to techniques disclosed herein, during the application of a programming pulse (VPGM) to a selected word line, a Quick Pass Write (QPW) voltage (VQPW) can be applied to bit lines coupled to one or more memory cells determined for slow programming. The bit lines can be charged by turning on BLC transistors connect to the bit lines through apply a BLC QPW voltage (VBLC_QPW) to the gates of the BLC transistors. Timing of turning on the BLC transistors and charging the bit lines can be set to certain time windows of a program loop (also referred to herein as sub-clocks). Based on the assigned time window, earlier time windows can be allocated to at least one bit-scan of the program-verify operation, which can be performed to determine which memory cells are to be programmed via slow programming. For example, more time can be allocated for performing the at least one bit-scan dependent upon the BLC transistor being turned on after applying the VPGM to the selected word line. Compared to conventional approaches, which activate the BLC transistors prior to applying the VPGM, examples herein can activate the BLC transistors later which permits flexible allocation of the sub-clocks. These techniques can provide for improved performance with reduced programming delays over other program-verify techniques and are discussed in further detail below.

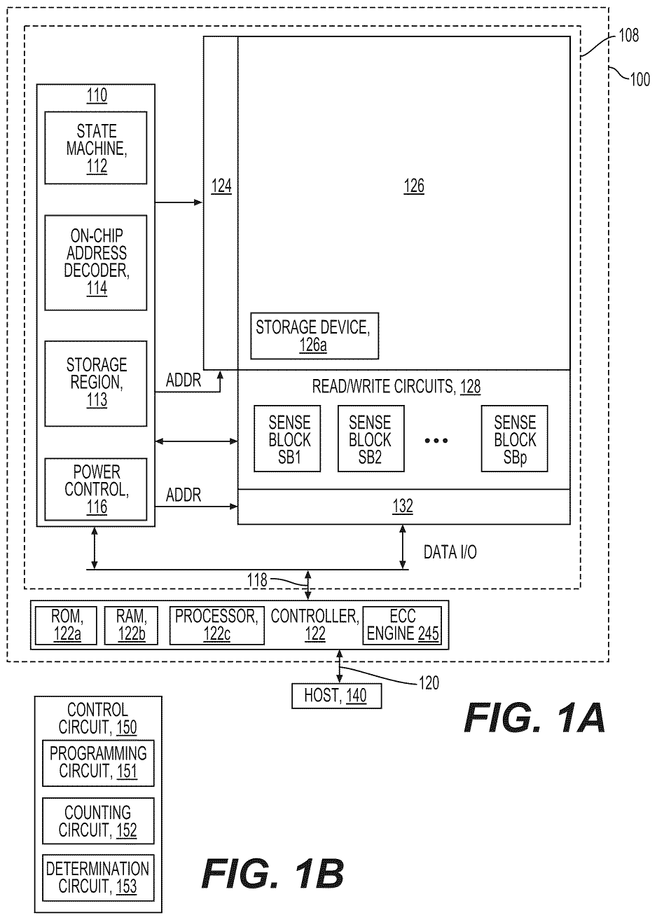

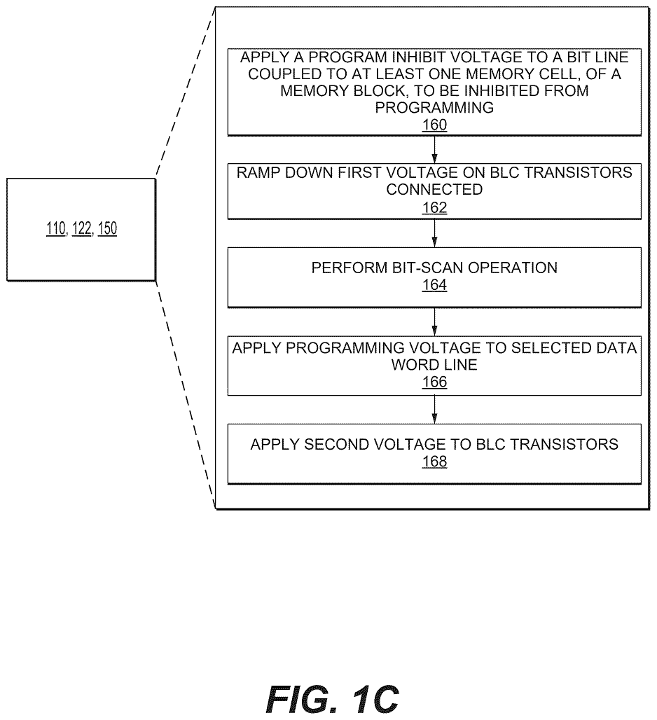

FIG. 1A is a block diagram of an example memory device 100 that is configured to operate according to the pre-charging techniques of the present disclosure. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks SB1, SB2, . . . SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more array of memory cells including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . , SBp, read/write circuits 128, controller 122, and so forth.

The control circuits can include a programming circuit configured to perform a program and program-verify operation for one set of memory cells, wherein the one set of memory cells comprises memory cells assigned to represent one data state among a plurality of data states and memory cells assigned to represent another data state among the plurality of data states; the program and program-verify operation comprising a plurality of program and program-verify iterations; and in each program and program-verify iteration, the programming circuit performs programming for the one selected word line after which the programming circuit applies a programming pulse. The control circuits can also include a counting circuit configured to obtain a count of memory cells which pass a verify test for the one data state. The control circuits can also include a determination circuit configured to determine, based on an amount by which the count exceeds a threshold, if a programming operation is completed.

For example, FIG. 1B is a block diagram of an example control circuit 150 which comprises a programming circuit 151, a counting circuit 152, and a determination circuit 153.

The off-chip controller 122 may comprise a processor 122c, storage devices (memory) such as ROM 122a and RAM 122b and an error-correction code (ECC) engine 245. The ECC engine can correct a number of read errors, which are caused when the upper tail of a Vth distribution becomes too high. However, uncorrectable errors may exist in some cases. The techniques provided herein reduce the likelihood of uncorrectable errors.

The storage device(s) 122a, 122b comprise, code such as a set of instructions, and the processor 122c is operable to execute the set of instructions to provide the functionality described herein. Alternately or additionally, the processor 122c can access code from a storage device 126a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below.

FIG. 1C illustrates that the control circuitry 110, controller 122, and/or control circuit 150 are configured to operate according to the program-verify techniques of the subject disclosure. Specifically, these components are configured to apply a programming voltage (VPGM) to a selected data word line during a program-verify operation.

At step 160, a program inhibit voltage is applied to a bit line coupled to at least one memory cell, of a memory block, to be inhibited from programming. The memory block includes a plurality of memory cells connect to a plurality of word lines. At step 162, a first voltage (e.g., VTH_BLDR) on a gates of a bit line clamp (BLC) transistors connected to bit lines of the memory block is ramped down. At step 164, a bit-scan is performed to verify a threshold voltage of one or more memory cells connected to a selected data word line is above a verify low voltage. The bit-scan may determine which memory cells, if any, are to be programmed slowly because the threshold voltage may be between the verify low voltage and a verify high voltage of an intended data state. At step 166, during the bit-scan, a programming voltage (VPGM) is applied to the selected data word line. At step 168, a second voltage (e.g., VBLC_QPW) is applied to the gates of the BLC transistors after the bit-scan is completed, which charges the bit lines coupled to the memory cells to be programmed slowly to a QPW voltage (VQPW). Memory cells to be programmed (e.g., those on the selected word line having threshold voltages below the verify low voltage) are maintained at a resting voltage (e.g., ground, 0 volts, or another appropriate resting voltage). Due to the difference between the resting voltage and a drain-side select gate voltage (VSGD), there is sufficient conduction in on the drain-side select gate of the memory cells to be programmed, which permits programming. Whereas application of the VQPW voltage to the bit lines of memory cells to be programmed slowly increases the voltage in the channels, thereby reducing the voltage difference between the programming pulse VPGM and the channels and slowing the flow of electrons into the charge trapping materials of the memory cells being programmed. In examples, the timing of the ramping down the first voltage on the gates of the BLC transistors and initiating the bit-scan is dependent upon a timing at which the voltage is to be applied to the gates of the BLC transistors.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further, by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate, which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x- and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements, which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

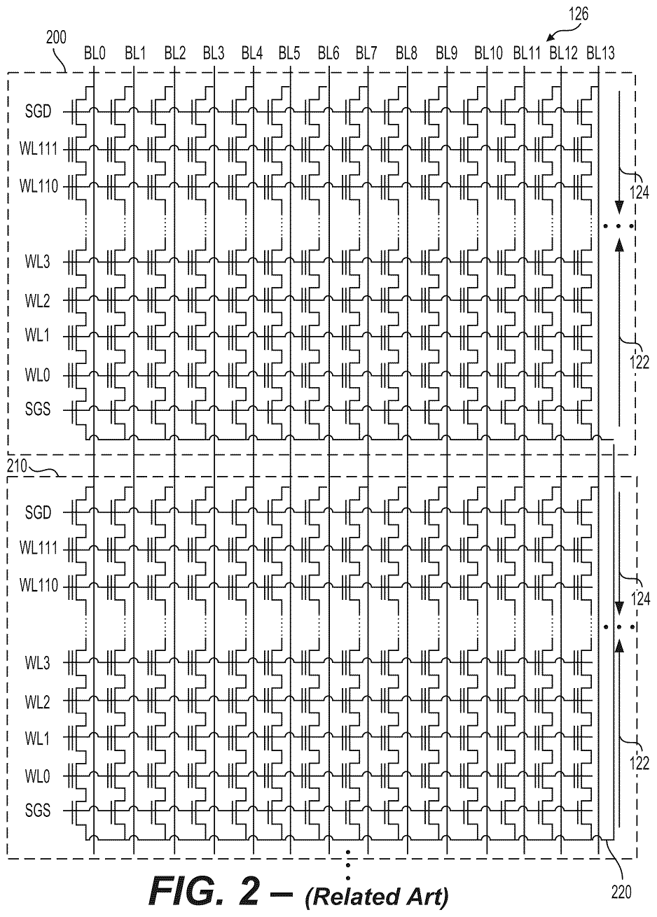

FIG. 2 illustrates blocks 200, 210 of memory cells in an example two-dimensional configuration of the memory array 126 of FIG. 1. The memory array 126 can include many such blocks 200, 210. Each example block 200, 210 includes a number of NAND strings and respective bit lines, e.g., BL0, BL1, . . . , which are shared among the blocks. Each NAND string is connected at one end to a drain-side select gate (SGD), and the control gates of the drain select gates are connected via a common SGD line. The NAND strings are connected at their other end to a source-side select gate (SGS) which, in turn, is connected to a common source line 220. One hundred and twelve data word lines, for example, WL0-WL111, extend between the SGSs and the SGDs. In some embodiments, the memory block may include more or fewer than one hundred and twelve data word lines. For example, in some embodiments, a memory block includes one hundred and sixty-four data word lines. In some cases, dummy word lines, which contain no user data, can also be used in the memory array adjacent to the select gate transistors. Such dummy word lines can shield the edge data word line from certain edge effects. As used herein, the term “word lines” may be refer to collections of dummy word lines and data word lines and the term “word line” may refer to a dummy word line or a data word lines, unless explicitly stated as to which type of word line is referenced.

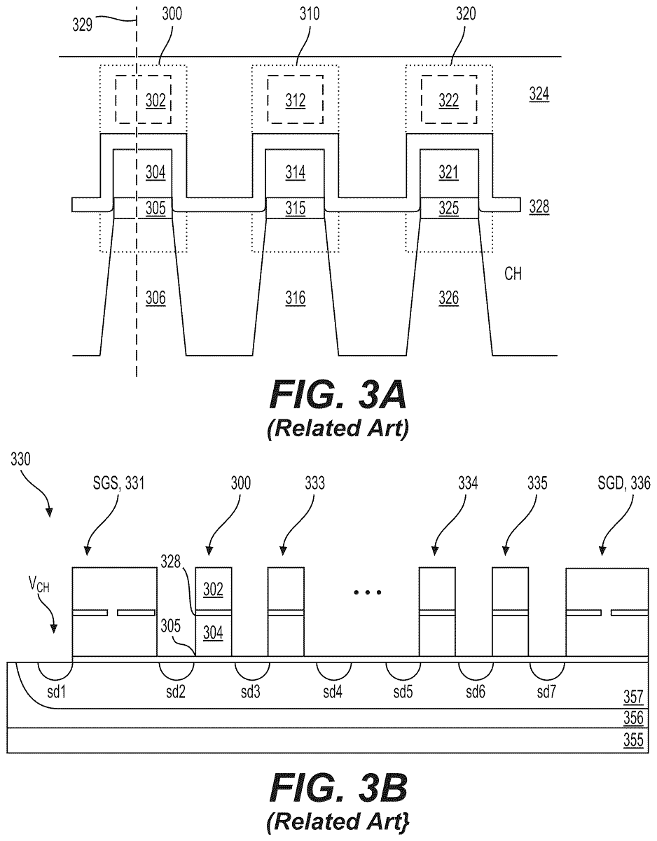

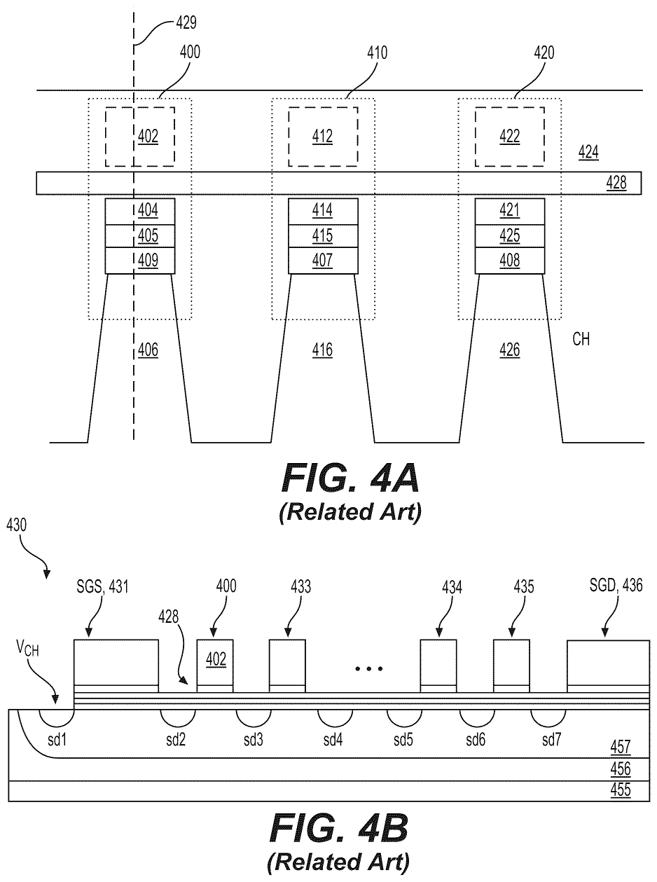

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings, which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio, which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings, which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433, . . . 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (O) such as in a N—O—N—O—N configuration.

The NAND string may be formed on a substrate that comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, VCH, may be applied directly to the channel region of the substrate.

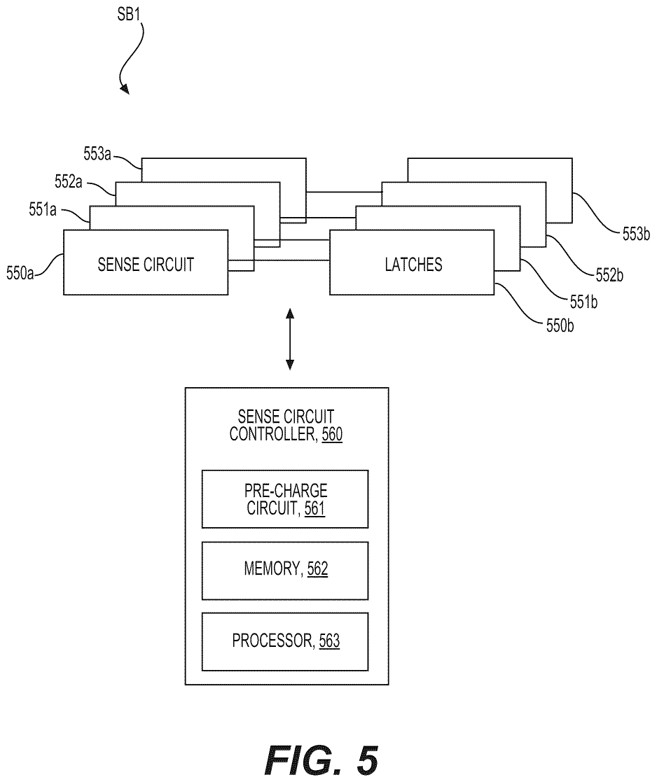

FIG. 5 illustrates an example block diagram of the sense block SB1 of FIG. 1. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load, which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561, which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code, which is executable by the processor to perform the functions described herein. These functions can include reading the latches 550b, 551b, 552b, 553b that are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

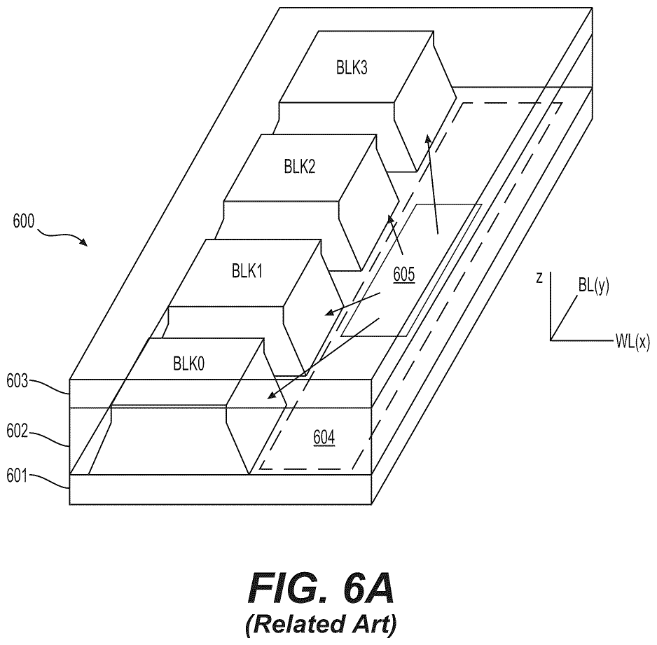

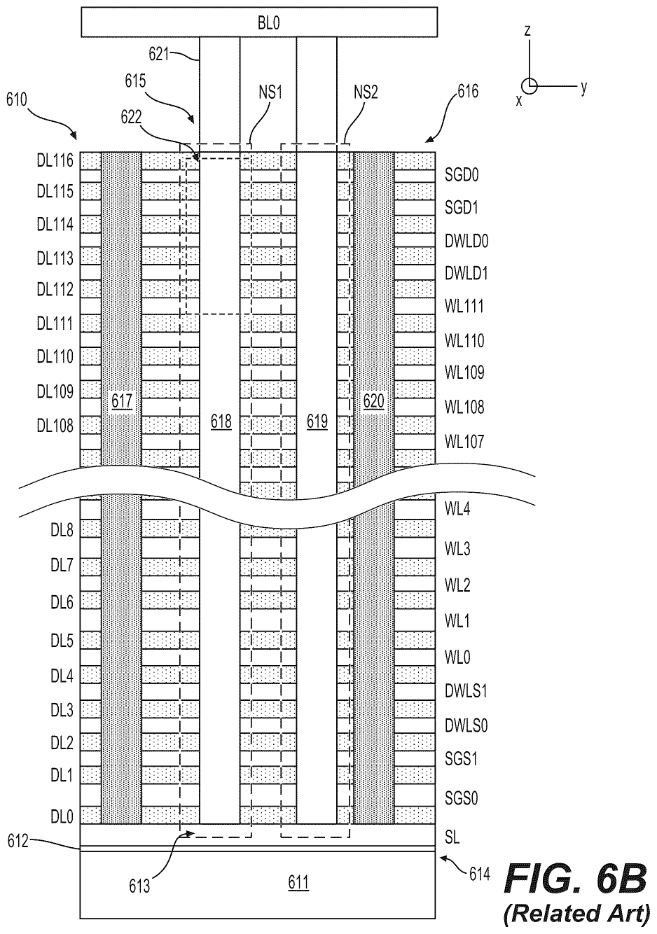

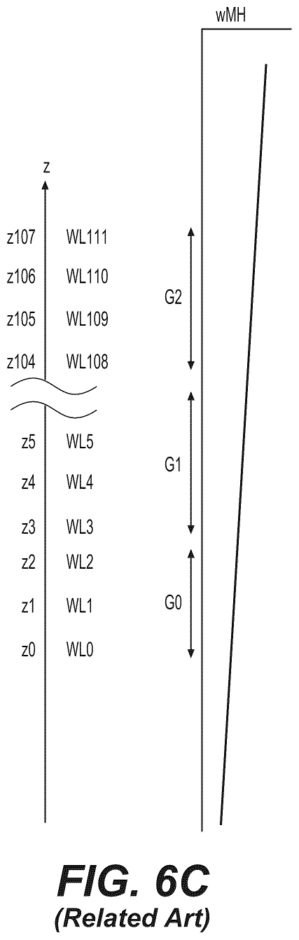

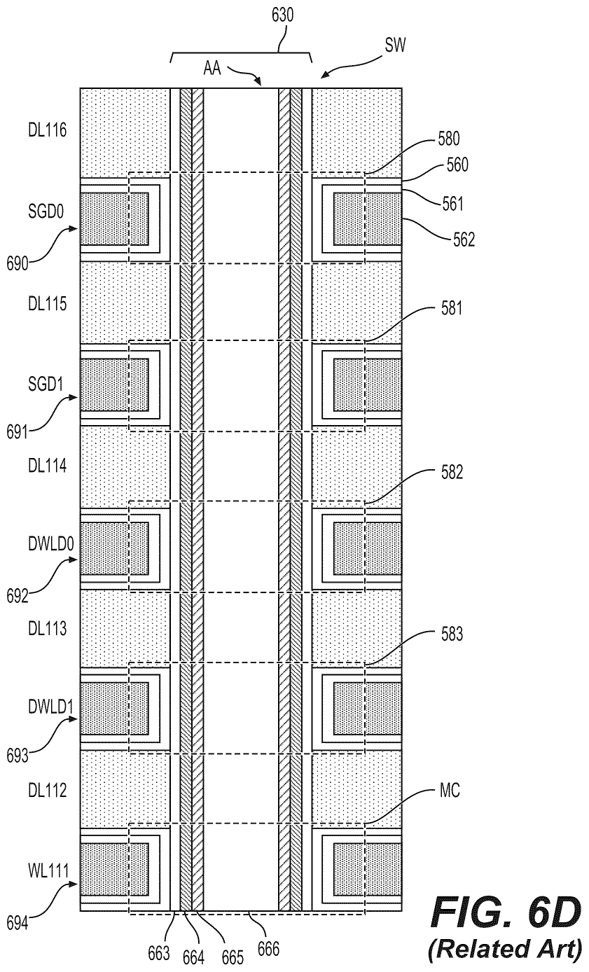

FIG. 6A is a perspective view of a set of blocks 600 in an example three-dimensional configuration of the memory array 126 of FIG. 1. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605, which can be connected to control gate layers of the blocks BLK0, BLK1, BLK2, and BLK3. In one approach, control gate layers at a common height in the blocks BLK0, BLK1, BLK2, and BLK3 are commonly driven. The substrate 601 can also carry circuitry under the blocks BLK0, BLK1, BLK2, BLK3, along with one or more lower metal layers, which are patterned in conductive paths to carry signals of the circuitry. The blocks BLK0, BLK1, BLK2, and BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, and BLK3 are illustrated as an example, two or more blocks can be used, extending in the x- and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers WL0-WL111. The dielectric layers are labelled as DL0-DL116. Further, regions of the stack 610 which comprise NAND strings NS1 and NS2 are illustrated. Each NAND string encompasses a memory hole 618, 619 that is filled with materials, which form memory cells adjacent to the word lines. A region 622 of the stack 610 is shown in greater detail in FIG. 6D and is discussed in further detail below.

The 610 stack includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WL0-WL111 of FIG. 6A are repeated as an example and are at respective heights z0-z111 in the stack. In such a memory device, the memory holes which are etched through the stack have a very high aspect ratio. For example, a depth-to-diameter ratio of about 24-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

Due to the non-uniformity in the width of the memory hole, the programming speed, including the program slope and erase speed of the memory cells can vary based on their position along the memory hole, e.g., based on their height in the stack. With a smaller diameter memory hole, the electric field across the tunnel oxide is relatively stronger, so that the programming and erase speed is relatively higher. One approach is to define groups of adjacent word lines for which the memory hole diameter is similar, e.g., within a defined range of diameter, and to apply an optimized verify scheme for each word line in a group. Different groups can have different optimized verify schemes.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar that is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal 662 such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer, which is associated with the memory cell. These electrons are drawn into the charge-trapping layer from the channel, and through the tunneling layer. The Vth of a memory cell is increased in proportion to the amount of stored charge. During an erase operation, the electrons return to the channel.

Each of the memory holes 630 can be filled with a plurality of annular layers comprising a blocking oxide layer, a charge trapping layer 663, a tunneling layer 664 and a channel layer. A core region of each of the memory holes 630 is filled with a body material, and the plurality of annular layers are between the core region and the word line in each of the memory holes 630.

The NAND string can be considered to have a floating body channel because the length of the channel is not formed on a substrate. Further, the NAND string is provided by a plurality of word line layers above one another in a stack, and separated from one another by dielectric layers.

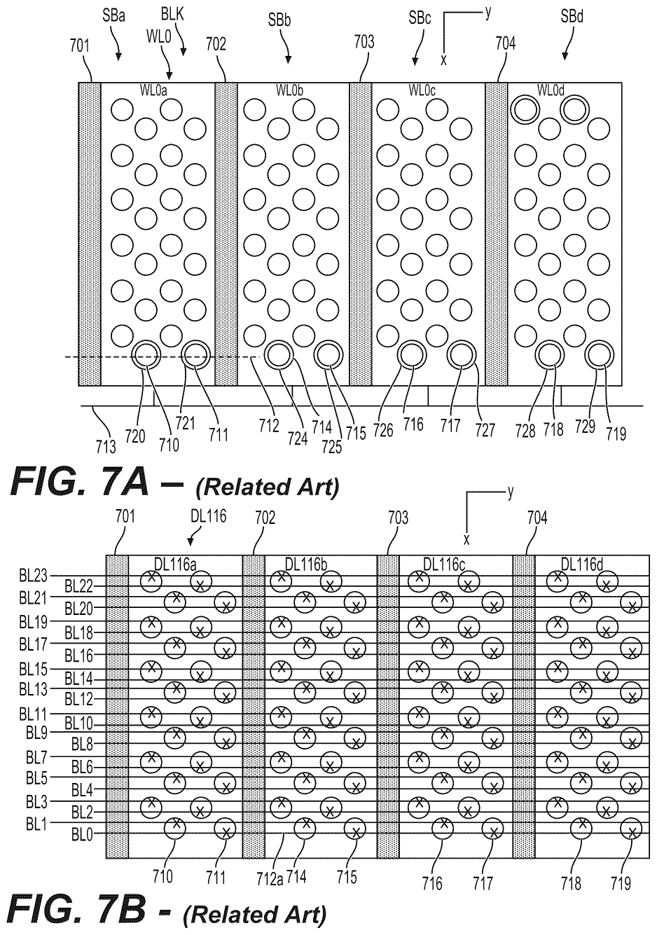

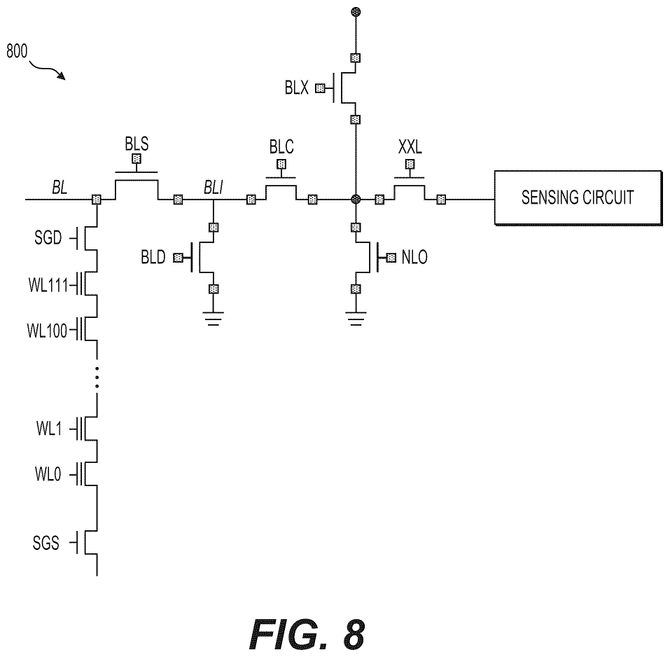

FIG. 7A illustrates a top view of an example data word line layer WL0 of the stack 610 of FIG. 6B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are data word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group, which has a common SGD control line. For example, see the SGD lines/control gates SGD0, SGD1, SGD2 and SGD3 in the sub-blocks SBa, SBb, SBc and SBd, respectively. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void, which is created by the removal of the sacrificial material. For example, the distance between contact line connectors may allow for a few rows of memory holes between adjacent contact line connectors. The layout of the memory holes and contact line connectors should also account for a limit in the number of bit lines, which can extend across the region while each bit line is connected to a different memory cell. After processing the data word line layers, the contact line connectors can optionally be filed with metal to provide an interconnect through the stack.

In this example, there are four rows of memory holes between adjacent contact line connectors. A row here is a group of memory holes, which are aligned in the x-direction. Moreover, the rows of memory holes are in a staggered pattern to increase the density of the memory holes. The data word line layer or data word line is divided into regions WL0a, WL0b, WL0c and WL0d that are each connected by a contact line 713. The last region of a data word line layer in a block can be connected to a first region of a data word line layer in a next block, in one approach. The contact line 713, in turn, is connected to a voltage driver for the data word line layer. The region WL0a has example memory holes 710, 711 along a contact line 712. The region WL0b has example memory holes 714, 715. The region WL0c has example memory holes 716, 717. The region WL0d has example memory holes 718, 719. The memory holes are also shown in FIG. 7B. Each memory hole can be part of a respective NAND string. For example, the memory holes 710, 714, 716 and 718 can be part of NAND strings NS0_SBa, NS1_SBb, NS2_SBc, NS3_SBd, and NS4_SBe, respectively.

Each circle represents the cross-section of a memory hole at a data word line layer or SG layer. Example circles shown with dashed lines represent memory cells which are provided by the materials in the memory hole and by the adjacent data word line layer. For example, memory cells 720, 721 are in WL0a, memory cells 724, 725 are in WL0b, memory cells 726, 727 are in WL0c, and memory cells 728, 729 are in WL0d. These memory cells are at a common height in the stack.

Contact line connectors (e.g., slits, such as metal-filled slits) 701, 702, 703, 704 may be located between and adjacent to the edges of the regions WL0a-WL0d. The contact line connectors 701, 702, 703, 704 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 7B illustrates a top view of an example top dielectric layer DL116 of the stack of FIG. 6B. The dielectric layer is divided into regions DL116a, DL116b, DL116c and DL116d. Each region can be connected to a respective voltage driver. This allows a set of memory cells in one region of a data word line layer being programmed concurrently, with each memory cell being in a respective NAND string, which is connected to a respective bit line. A voltage can be set on each bit line to allow or inhibit programming during each program voltage.

The region DL116a has the example memory holes 710, 711 along a contact line 712, which is coincident with a bit line BL0. A number of bit lines extend above the memory holes and are connected to the memory holes as indicated by the “X” symbols. BL0 is connected to a set of memory holes, which includes the memory holes 711, 715, 717, 719. Another example bit line BL1 is connected to a set of memory holes, which includes the memory holes 710, 714, 716, 718. The contact line connectors (e.g., slits, such as metal-filled slits) 701, 702, 703, 704 from FIG. 7A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

FIG. 8 generally illustrates an implementation of a sensing circuit 800, in accordance with an embodiment of the present disclosure. Sensing circuit 800 may be an example implementation of one of sensing circuits 550a, 551, 552a, 553a. As such, sensing circuit 800 may be associated with a corresponding data latch, as described above in connection with FIG. 5. The sensing circuit 800 comprise a NAND string connected to a respective bit line (BL). The BL may be an example implementation of a bit line included in memory array 126 (e.g., BL0, BL1, etc. as shown in FIG. 2). The NAND string is connected at one end to an SGD, and the control gates of the drain select gates are connected via a common SGD line. The NAND strings are connected at their other end to an SGS.

Further, as shown in FIG. 8, sense circuit 800 includes transistors BLS, bit line clamp (BLC), BLX, XXL and NLO. The BL communicates with the BLS transistor and the BLC transistor. The BLS transistor is a high-voltage transistor that can isolate the sensing circuit, which has low voltage transistors, from high voltages of the memory array. During sensing, BLS is conductive. The BLC transistor can clamp a voltage on a bit line by control of its gate voltage and supply of a sufficiently high voltage on the drain of the BLC transistor. Still yet, in FIG. 8, sense circuit 800 includes a bit line discharge (BLD) transistor, which is configured to discharge HV from the BL. In some embodiments, a BLD signal may be controlled by data latches (e.g., a data latch associated with the sensing circuit as described above in connection with FIG. 5) in a local bus (LBUS). With output of the data latches, the BLD transistor can be turned on or turned off individually. Hence, bitline-by-bitline control may be achieved.

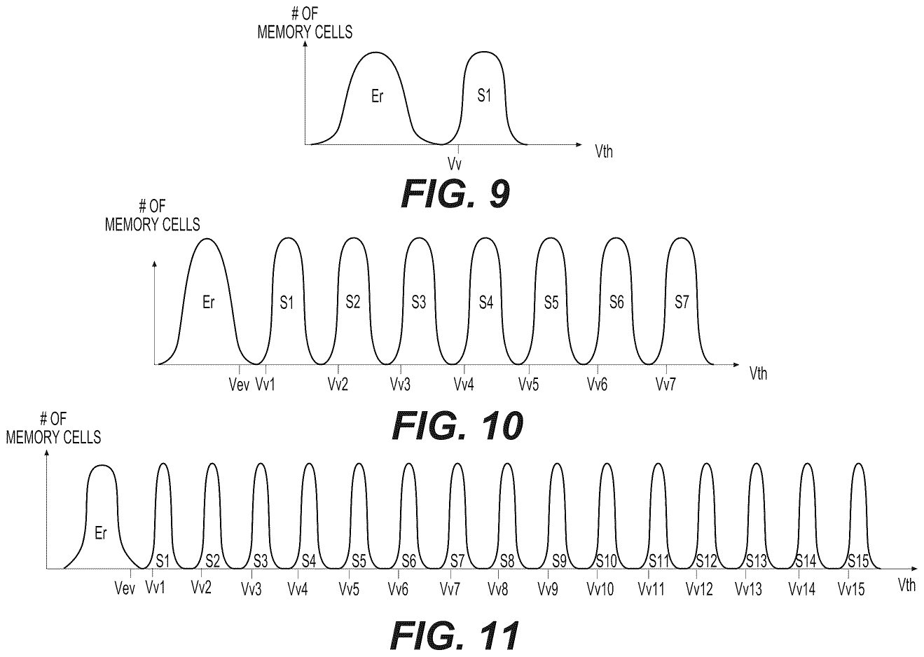

The memory cells of the memory blocks discussed above can be erased, programmed and read. At the end of a successful programming operation, threshold voltages of the memory cells should be within one or more distributions of threshold voltages for programmed memory cells or within a distribution of threshold voltages for erased memory cells, as appropriate. For example, FIG. 9 depicts a threshold voltage Vth distribution of a group of memory cells programmed according to a one bit per memory cell (SLC) storage scheme. In the SLC storage scheme, there are two data states, including the erased state (Er) and a single programmed data state (S1). FIG. 9 shows two threshold voltage distributions, one for the erased state (Er) and the single programmed data state (S1). Memory cells that have threshold voltages in threshold voltage distribution Er are, therefore, in the erased data state (e.g., they are erased). Memory cells that have threshold voltages in threshold voltage distribution S1 are, therefore, in the programmed data state (e.g., they are programmed). By testing (e.g., performing one or more sense operations) whether the threshold voltage of a given memory cell is above or below a read compare voltage Vr, the memory device can determine a memory cell is in the erased state (Er) or programmed data state (S1). Furthermore, FIG. 9 depicts a verify reference voltage Vv. In some embodiments, when programming memory cells to programmed data state S1, the memory device can test whether those memory cells have a threshold voltage greater than or equal to Vv.

FIGS. 10 and 11 illustrate example threshold voltage distributions for the memory array when each memory cell stores multiple bits per memory cell data. Memory cells that store multiple bits per memory cell data are referred to as multi-level cells (“MLC”). FIG. 10 illustrates the threshold voltage Vth distribution of a three bits per cell (TLC) storage scheme that includes eight total data states, namely the erased state (Er) and seven programmed data states (S1, S2, S3, S4, S5, S6, and S7). FIG. 11 depicts a threshold voltage Vth distribution of a four bits per cell (QLC) storage scheme that includes sixteen total data states, namely the erased state (Er) and fifteen programmed data states (S1-S15). Other storage schemes are also available, such as two bits per cell with four data states or five bits per cell (PLC) with thirty-two data states.

Referring to FIG. 10 as an illustrative example, each programmed data state (S1-S7) is associated with a respective read compare voltage (Vr1-Vr7), which can be employed for reading data from memory cells. By testing (e.g., performing sense operations) whether the threshold voltage of a given memory cell is above or below the read compare voltages, the memory device can determine what data state (i.e., S1-S7) a memory cell is in. Note that, while not explicitly shown in FIG. 10 for legibility purposes, each programmed data state (S1-S15) can be associated with a respective read compare voltage (Vr1-Vr15).

Each programmed data state (S1-S7) is also associated with a respective verify voltage (Vv1-Vv7), which is employed during a program verify portion of a programming operation. In some embodiments, when programming memory cells to data state S1, the memory device will test whether those memory cells have a threshold voltage greater than or equal to Vv1. When programming memory cells to data state S2, the memory device will test whether the memory cells have threshold voltages greater than or equal to Vv2. Thus, for example, when programming memory cells to a data state, the memory device will determine whether memory cells have their threshold voltage greater than or equal to the respective verify voltage. FIG. 10 also shows a verify voltage Vev, which is a voltage level to test whether a memory cell has been properly erased.

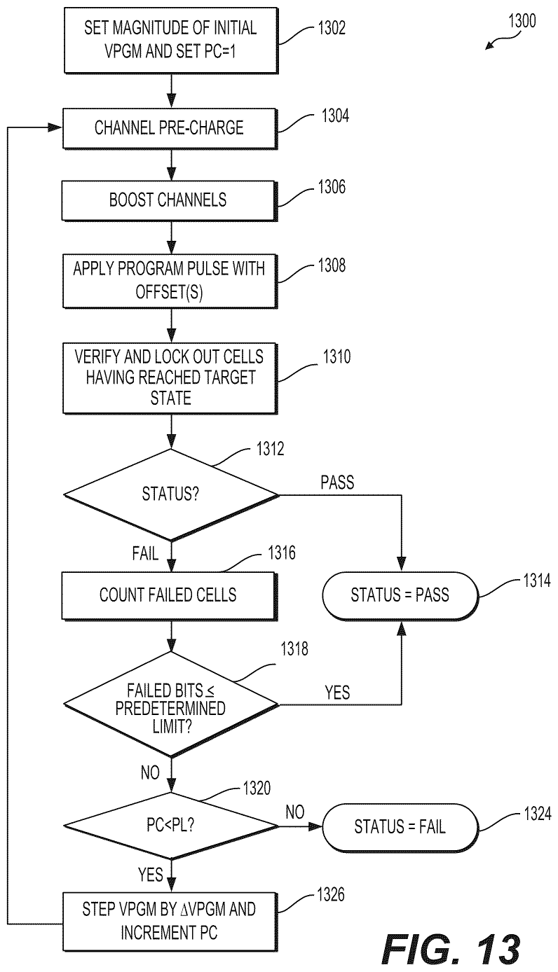

In an embodiment that utilizes full sequence programming, memory cells can be programmed from the erased data state Er directly to any of the programmed data states (e.g., S1-S7 in the example of FIG. 10) using the process of FIGS. 13 and/or 15 (discussed below). For example, a population of memory cells to be programmed may first be erased so that all memory cells in the population are in the erased state Er. Then, a programming process is used to program memory cells directly into programmed data states (e.g., S1-S7 in the example of FIG. 10). For example, while some memory cells are being programmed from erased state Er to programmed data state S1, other memory cells can be programmed from erased state Er to programmed data state S2 and/or from to programmed data state S3, and so on. In some embodiments, programmed data states can overlap, with control circuitry 110, controller 122, and/or control circuit 150 relying on error correction to identify the correct data being stored. Note that in some embodiments, rather than using full sequence programming, the system can use multi-pass programming processes known in the art.

In general, during program-verify operation and read operations, a selected data word line is connected to a voltage (one example of a reference signal), a level of which is specified for each read operation (e.g., read compare voltage Vr1-Vr7 in the example of FIG. 10) or program-verify operation (e.g. verify voltages Vv1-Vv7 in the example of FIG. 10) in order to determine whether a threshold voltage of the concerned memory cell has reached such level. After applying the data word line voltage, the conduction current of the memory cell is measured to determine whether the memory cell turned on (conducted current) in response to the voltage applied to the data word line. If the conduction current is measured to be greater than a certain value, then it is assumed that the memory cell turned on and the voltage applied to the data word line is greater than the threshold voltage of the memory cell. If the conduction current is not measured to be greater than the certain value, then it is assumed that the memory cell did not turn on and the voltage applied to the data word line is not greater than the threshold voltage of the memory cell. During a read or program-verify operation, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or program-verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

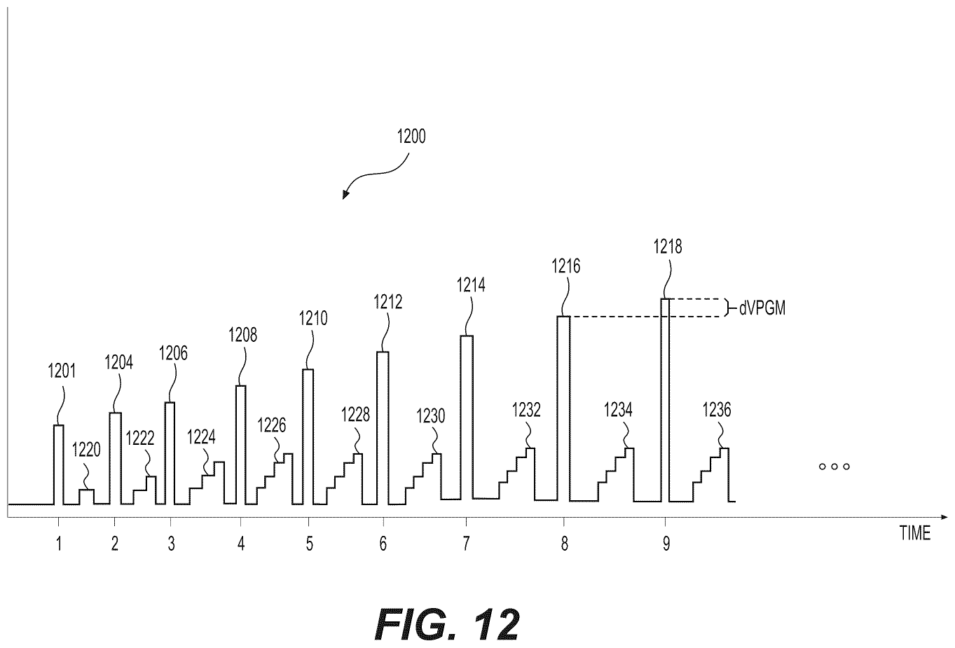

FIG. 12 depicts a waveform 1200, or pulse train, of an example programming operation. The horizontal axis depicts time, and the vertical axis depicts control gate or word line voltage through multiple program-verify iterations. A square waveform is depicted for each programming pulse and each verify pulse for simplicity; however, other shapes are possible, such as a multilevel shape or a ramped shape. Further, Incremental Step Pulse Programming (ISPP) is used in this example, in which a programming (VPGM) pulse 1202-1218 amplitude steps up in each successive program loop by a fixed increment amount, e.g., dVpgm.

A pulse train starts at an initial VPGM pulse level and ends at a final VPGM pulse level, which does not exceed a maximum allowed level. The pulse train 1200 includes a series of VPGM pulses 1202, 1204, 1206, 1208, 1210, 1212, 1214, 1216, 1218 . . . that are applied to the control gate of the selected word line. One, two, three, or more verify voltage pulses 1220-1236 are provided after each VPGM pulse 1202-1218 as an example, based on the target memory states which are being verified in each program-verify iteration. A voltage of 0 V may be applied to the control gate of the selected word line between the VPGM pulses and verify voltage pulses.

FIG. 13 is a flowchart describing one embodiment of a process 1300 for programming memory cells. For purposes of this document, the term program and programming are synonymous with write and writing. In one example embodiment, the process 1300 can be performed for memory array 126 using the one or more control circuits (e.g., control circuitry 110, controller 122, and/or controller 150) discussed above. The process 1300 may include multiple loops (referred to as program loops), each of which includes a program operation and a program-verify operation. The process 1300 can be performed to implement the full sequence programming, as well as other programming schemes including multi-pass programming, which comprises programming processes that use multiple passes to complete programming. When implementing multi-pass programming, the process 1300 can be used to implement any/each pass of the multi-pass programming process.

A program loop of a program operation includes the following stages: P_CLK (preparation clock as a precursor to actual programming), PD_CLK (program duration clock during which actual programming occurs), PR_CLK (program-recovery clock), and RR_CLK (read-recovery clock as a final phase of a program verify operation, which can be following by the P_CLK). The P_CLK includes bit line and word line voltage ramping and pre-charging. During P_CLK, selective word lines ramp up (e.g., pre-charged) to VPGM and unselected work lines ramp to VPASS. During PD_CLK, the signal is plateaued and memory cells are programmed. In the RR_CLK, word line voltages are brought back to ground to be prepared for the next program loop. RR_CLK is also where some bit-scan operations may happen as part of program-verify operations that verify that memory cells have reached target states and can be locked out from further programming during a next program loop. Each stage may be divided into multiple sub-clocks (or time windows) during which certain actions of the program operation can be performed. For example, the P_CLK may be divided into 15 sub-blocks (P1-P15). The PD_CLK can likewise be divided into multiple sub-clocks, such as but not limited to 10 sub-blocks (e.g., PD1, PD2, PD3, . . . PD10).

During a program operation, the program voltage is applied to the control gates (via a selected data word line) as a series of program pulses (e.g., voltage pulses). Between programming pulses are a set of verify pulses (e.g., voltage pulses) to perform verification. In many implementations, the magnitude of the program pulses is increased with each successive pulse by a predetermined step size. In step 1302, the programming voltage signal (VPGM) is initialized to a starting magnitude (e.g., between approximately 12 and −16V or another suitable level) and a program counter PC maintained by state machine 112 is initialized at 1, In an example, a group of memory cells selected to be programmed (referred to herein as the selected memory cells) are programmed concurrently and are all connected to the same data word line (referred to herein as the selected data word line). There will likely be other memory cells that are not selected for programming (referred to herein as unselected memory cells) that are also connected to the selected data word line. That is, the selected data word line may also be connected to memory cells that are to be inhibited from programming. Additionally, as memory cells reach their intended target data state, they will be inhibited from further programming. Those NAND strings (e.g., unselected NAND strings) that include memory cells connected to the selected data word line that are to be inhibited from programming have their channels boosted to inhibit programming. When a channel has a boosted voltage, the voltage differential between the channel and the data word line is not large enough to cause programming. To assist in the boosting, in step 1304 the control die will pre-charge channels of NAND strings that include memory cells connected to the selected data word line that are to be inhibited from programming. In some embodiments, pre-charging the channels of unselected NAND strings cleans out the channel of electrons and raises the channel to a low positive voltage (e.g., approximately 1-1.3 v). In step 1306, NAND strings that include memory cells connected to the selected data word line that are to be inhibited from programming have their channels boosted to inhibit programming. Such NAND strings are referred to herein as “unselected NAND strings.” In some examples, the unselected data word lines receive one or more boosting voltages (e.g., approximately 7-11 volts), also referred to as pass voltages (VPASS), to perform boosting schemes. A program inhibit voltage (VHSA) is applied to the bit lines coupled the unselected NAND string prior to boosting the channel via VPASS. In one example, the channel is pre-charged to 2 volts in step 1304 and then floated. In step 1306, the channel is boosted up from the 2 volts to a boosting voltage of approximately 8-10 volts.

In step 1308, a program voltage pulse of the programming voltage signal VPGM is applied to the selected data word line (the data word line selected for programming). In some embodiments, the magnitude and/or pulse width of the program voltage pulse can be modified from the standard magnitude and/or pulse width by one or more offsets, as described below. If a memory cell on a NAND string should be programmed, then the corresponding bit line is biased at a program enable voltage. In step 1308, the program pulse is concurrently applied to all memory cells connected to the selected data word line so that all of the memory cells connected to the selected data word line are programmed concurrently (unless they are inhibited from programming). That is, they are programmed at the same time or during overlapping times (both of which are considered concurrent). In this manner all of the memory cells connected to the selected data word line will concurrently have their threshold voltage change, unless they are inhibited from programming. Step 1308 may be performed at the end of the P_CLK and plateaued during the PD_CLK.

In step 1310, program-verify operation is performed and memory cells that have reached their target states can be locked out from further programming by the one or more control circuits (e.g., system control circuitry 110, controller 122, controller 150 and/or sense circuit controller 550). The program-verify operation may include one or more sensing operations and one or more bit-scans. For example, step 1310 includes performing verification of programming by sensing the threshold voltages of the memory cells selected for programming (e.g., one or more sensing operations) and verifying that the sensed voltages are at one or more verify compare levels (e.g., one or more bit-scans). The results of the sensing operations can be collected in a data-latch and used for the one or more bit-scans. In some examples, the program-verify operation is performed by testing whether the threshold voltages of the memory cells selected for programming have reached the appropriate verify voltage in preparation for a next program pulse. In an example that corresponds to FIG. 10, the process 1300 can be concurrently performed for memory cells being programmed to data states S1, S2, S3, S4, S5, S6, and S7. In this example, step 1310 can include testing for each of data states S1, S2, S3, S4, S5, S6, and S7 (e.g., testing to see whether memory cells have threshold voltages greater than Vv1, Vv2, Vv3, Vv4, Vv5, Vv6, and Vv7). In another example, the system may test for a subset of data states S1, S2, S3, S4, S5, S6, and S7 during each loop of steps 1304-1326 based on the current threshold voltages of the memory cells, in what is known as a smart verify process. In step 1310, a memory cell may be locked out after the memory cell has been verified (by a test of the Vth) that the memory cell has reached its target state. The program-verify operation (or portions thereof) may be performed during the RR_CLK.

If, in step 1312, it is determined that all of the memory cells have reached their target threshold voltages (pass), the programming process is complete and successful because all selected memory cells were programmed and verified to their target states. A status of “PASS” is reported in step 1314. Otherwise, if in step 1312, it is determined that not all of the memory cells have reached their target threshold voltages (fail), then the programming process continues to step 1316.

In step 1316, the number of memory cells that have not yet reached their respective target threshold voltage distribution are counted. That is, the number of memory cells that have, so far, failed to reach their target state are counted. This counting can be done by state machine 112, circuitry 110, controller 122, control circuit 150, and/or another circuit. In an example, there may be one total count, which reflects the total number of memory cells currently being programmed that have failed the last verify step. In another example, separate counts are kept for each data state.

In step 1318, it is determined whether the count from step 1316 is less than or equal to a predetermined limit. In some examples, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 1314. In this situation, enough memory cells programmed correctly such that the few remaining memory cells that have not been completely programmed can be corrected using ECC during the read process. In some examples, the predetermined limit used in step 1318 is below the number of bits that can be corrected by error correction codes (ECC) during a read process to allow for future/additional errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, than the programming process continues at step 1320 and the program counter (PC) is checked against the program limit value (PL). Examples of program limit values include 6, 12, 16, 19, 20 and 30; however, other values can be used. If the program counter (PC) is not less than the program limit value (PL), then the program process is considered to have failed and a status of “FAIL” is reported in step 1324. If the program counter (PC) is less than the program limit value (PL), then the process continues at step 1326 during which time the Program Counter (PC) is incremented by 1 and the programming voltage signal VPGM is stepped up to the next magnitude. For example, the next pulse will have a magnitude greater than the previous pulse by a step size dVpgm (e.g., a step size of 0.1-1.0 volts). After step 1326, the process loops back to step 1304 and another program pulse is applied to the selected data word line (by the control die) so that another loop (steps 1304-1326) of the programming process 1300 is performed. The loop (steps 1304-1326) of the programming process 1300 may be referred to as a program loop.

In some embodiments, memory cells are programmed in an order from the source side to the drain side. For example, first the process 1300 is performed to program memory cells connected to WL0, followed by using the process 1300 to program memory cells connected to WL1, followed by using the process 1300 to program memory cells connected to WL2, followed by using the process of 1300 to program memory cells connected to WL3, . . . followed by using the process 1300 to program memory cells connected to the final WL (e.g., WL111 in the example of FIGS. 2, 6B, and 6C). This order of programming may be referred to as normal order programming (NOP).

In another embodiment, memory cells are programmed in an order from the drain side to the source side. For example, first the process 1300 is performed to program memory cells connected to the final WL111, followed by using the process 1300 to program memory cells connected to WL110, . . . followed by using the process of FIG. 13 to program memory cells connected to WL1, and followed by using the process 1300 to program memory cells connected to WL0. This order of programming may be referred to as reverse order programming (ROP).

In one embodiment memory cells are erased prior to programming. Erasing is the process of changing the threshold voltage of one or more memory cells from a programmed data state to an erased data state. For example, changing the threshold voltage of one or more memory cells from state S1 to state Er of FIG. 9, from states S1-S7 to state Er of FIG. 9, or from states S1-S15 to state Er of FIG. 10.

There is a continuing need to develop programming techniques which tighten the threshold voltage distributions of the programming data states in order to improve programming reliability but to do so in such a way that the improved reliability does not come at the expense of performance, i.e., programming time. One such programming technique is known as Quick Pass Write (QPW), which slows programming of the memory cells that have passed a verify low VL voltage but have not passed a verify high VH voltage for a given data state. To slow programming, during the application of a VPGM pulse to the control gate of a selected word line, a QPW voltage (VQPW) is applied to the bit lines coupled to the memory cells that have passed a verify low (VL) voltage associated with a programmed data state (e.g., data state S1). The QPW voltage increases the voltage in the channels containing the memory cells for which slow programming is desired, thereby reducing the voltage difference between the programming pulse VPGM and the channels and slowing the flow of electrons into the charge trapping materials of the memory cells being programmed. Any memory cell which passes a verify high (VH) voltage is then locked down, or inhibited, from further programming by applying an inhibit voltage VHSA to the bit lines coupled to those memory cells during subsequent VPGM pulses (e.g., inhibit programming by a next programming pulse).

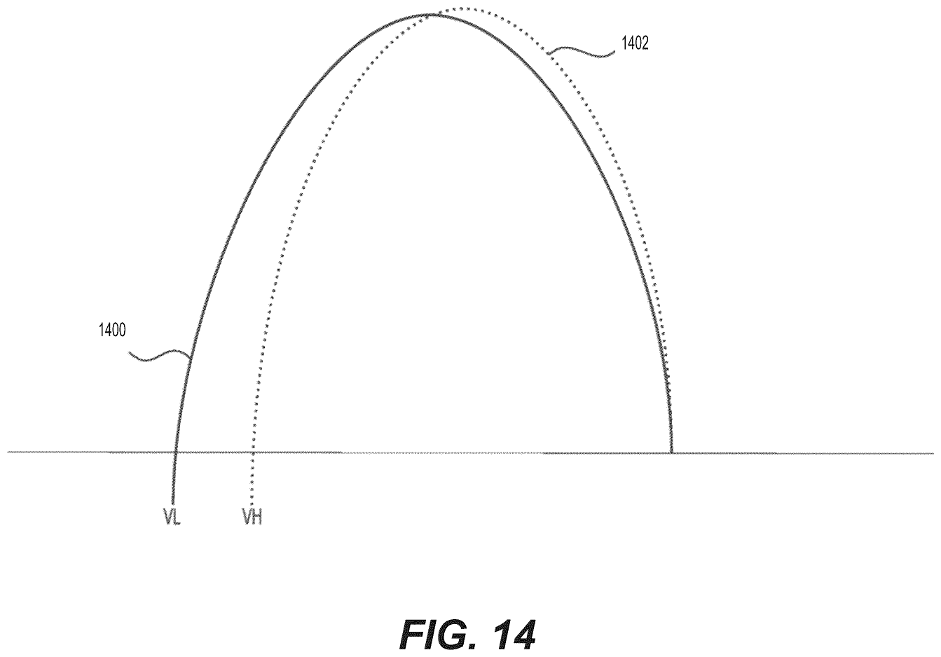

Turning now to FIG. 14, shown are the Vt distributions of the memory cells being programmed to a given programmed data state (e.g., data state S1) at different points in a programming operation. Curve 1400 identifies the Vt distribution of the memory cells after a given programming pulse, and curve 1402 identifies the Vt distribution of the same memory cells after a subsequent programming pulse. As shown, in curve 1400, some of the memory cells fall between verify low VL and verify high VH and some of the memory cells fall above verify high VH. During the subsequent programming pulse, programming is inhibited for the memory cells that fall above verify high VH, and programming is slowed via QPW programming for the memory cells that fell between verify low VL and verify high VH. After the subsequent programming pulse, curve 1402 illustrates that the Vt distribution has been tightened, and all of the memory cells now fall above VH.

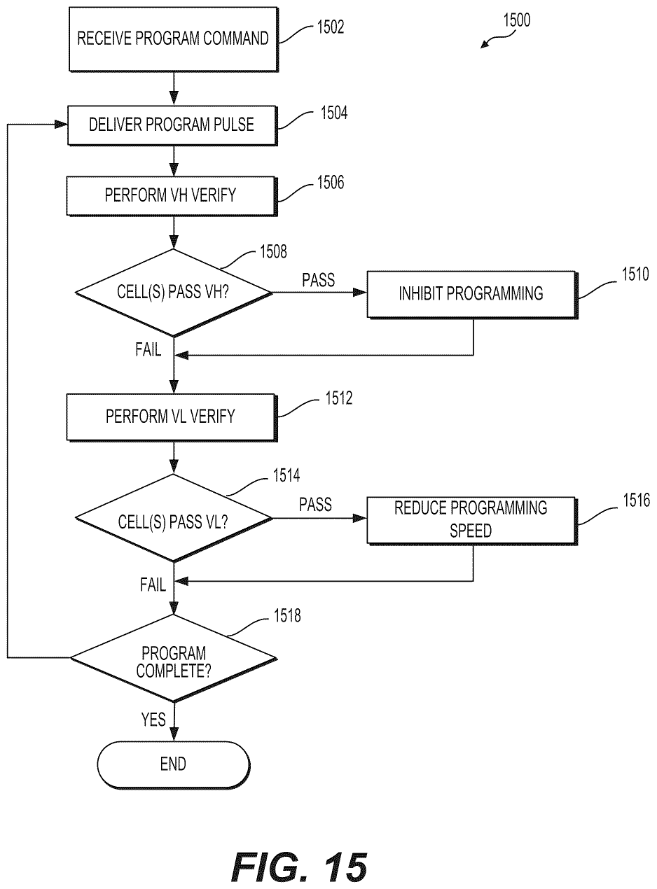

FIG. 15 illustrates an example of a process 1500 of applying QPW to program memory cells. The process 1500 includes receiving a program command at step 1502 (e.g., specifying data to be read at a location such as a word line) and delivering a program pulse at step 1504 (e.g., step 1308 of FIG. 13). Process 1500 includes performing program-verify operations at steps 1504-1516 to verify that memory cells have reached their target states and can be locked out from further programming (e.g., step 1310 of FIG. 13).

The process 1500 may include an operation of a program-verify operation that verifies whether threshold voltage of memory cells selected for programming have reached the verify high (VH) voltage associated with a programmed data state. At step 1506, the operation of the program-verify operation can be performed by applying appropriate signals to the data word lines, bit lines, source line and selected lines to perform a sensing (e.g., a second sensing operation) at one or more of the verify high voltages of the programmed data state (e.g., S1-S7 of FIG. 9), Step 1506 can include testing for each of data states S1, S2, S3, S4, S5, S6, and S7. In another example, the system may test for a subset of data states S1, S2, S3, S4, S5, S6, and S7 during each loop based on the current threshold voltages of the memory cells, in what is known as a smart verify process. The results of the second sensing process can be collected in one or more data latches. At step 1508, the operation of the program-verify operation may determine whether the selected memory cells being programmed have threshold voltages greater than the verify high voltage being tested for (e.g., threshold voltages passed or reached the VH voltage) (sometimes referred to herein as a second bit-scan, also referred to as a lockout high or lockoutH bit-scan). At step 1510, any memory cell which passes the VH voltage can be locked down, or inhibited, from further programming by applying a program inhibit voltage (VHSA) to the bit lines coupled to those memory cells during subsequent VPGM pulse. In examples, step 1508 (e.g., the second bit-scan) may be performed during the RR_CLK, while step 1506 (e.g., the second sensing operation) may be performed before the RR_CLK.

The process 1500 may include another operation of the program-verify operation that verifies whether threshold voltage of memory cells selected for programming (that have not reached the VH voltage) have reached the verify low (VL) voltage associated with a programmed data state. At step 1512, the operation of the program-verify operation can be performed by applying appropriate signals to the data word lines, bit lines, source line and selected lines to perform a sensing (e.g., a first sensing operation) at one or more of the verify low voltages of the programmed data state (e.g., S1-S7 of FIG. 9). The results of the first sensing process can be collected in one or more data latches. At step 1514, the operation of program-verify operation may determine whether the selected memory cells being programmed have threshold voltages greater than the verify low voltage being tested for (e.g., threshold voltages passed or reached the VL voltage) (sometimes referred to herein as a first bit-scan, also referred to as a lockout low or lockoutL bit-scan). During this time, memory cells that were determined to have passed the VH voltage at step 1506 are locked out from the sensing at step 1512. At step 1516, a QPW voltage (VQPW) is applied to the bit lines coupled to those memory cells that pass the verify low (VL) voltage associated with a programmed data state. As noted above, the QPW voltage increases the voltage in the channels containing the memory cells for which slow programming is desired, thereby reducing the voltage difference between the programming pulse VPGM and the channels and slowing the flow of electrons into the charge trapping materials of the memory cells being programmed. In examples, step 1514 (e.g., the first bit-scan) may be initiated during the P_CLK or the PD_CLK and may be completed during the P_CLK or the PD_CLK, while step 1512 (e.g., the first sensing operation) may be performed before the RR_CLK.). By applying the VTH_BLDR, BLC transistors can be operated in the linear region (as opposed to saturation region), which allows the entire BLC transistor channel to be in inversion. At time ta, the SGD is raised to VSGD (which is a voltage high enough to turn on a transistor for the selected gate, which may be approximately 3.5-6 v). The lockoutL bit-scan waits for the voltage on the BLC transistor (e.g., BLC of FIG. 15) to ramp down before initializing, which waits for the SGD to ramp down to VSS. Thus, at time tb (e.g., end of P7), the SGD is ramped down to VSS and the BLC is ramped down to VSS at time to (e.g., end of P9). This permits the channel to float (e.g., step 1304 of FIG. 13) and the lockoutL bit-scan can be performed during P10 to P13. Once the lockoutL bit-scan is complete and memory cells having a threshold voltage between VH and VL voltages are determined, the BLC signal can be ramped up to a BLC QPW voltage (VBLC_QPW), which is a voltage high enough to turn on the BLC transistor and pre-charge the selected bit lines. The VBLC_QPW may be lower than the VTH_BLDR, for example, VBLC_QPW may be significantly lower than VTH_BLDR (e.g., VBLC_QPW may be approximately 0.3V to 1.05V). Turning on the BLC transistors pre-charges the selected bit lines, particularly turning on the BLC transistor permits the voltage on the bit lines coupled to the memory cells determined during the lockoutL bit-scan (referred to as QPW bit lines or BL(QPW) to VQPW.

In examples, the operation of a program-verify operation that verifies whether threshold voltage of memory cells selected for programming have reached the verify high (VH) voltage associated with a programmed data state may be referred to as a second operation of the program-verify operation. In an example, the second operation of the program-verify operation can include a second sensing operation (e.g., applying appropriate signals to perform a sensing at one or more of the verify high voltages) and a second bit-scan operation (e.g., determining whether selected memory cells being programmed have threshold voltages greater than the verify high voltage). In this case, operation of the program-verify operation that verifies whether threshold voltage of memory cells selected is between the VH voltage and the verify low (VL) voltage may be referred to as a first operation of the program-verify operation. In an example, the first operation of the program-verify operation can include a first sensing operation (e.g., applying appropriate signals to perform a sensing at one or more of the verify low voltages) and a first bit-scan operation (e.g., determining whether selected memory cells being programmed have threshold voltages between the verify low voltage and the verify high voltage).

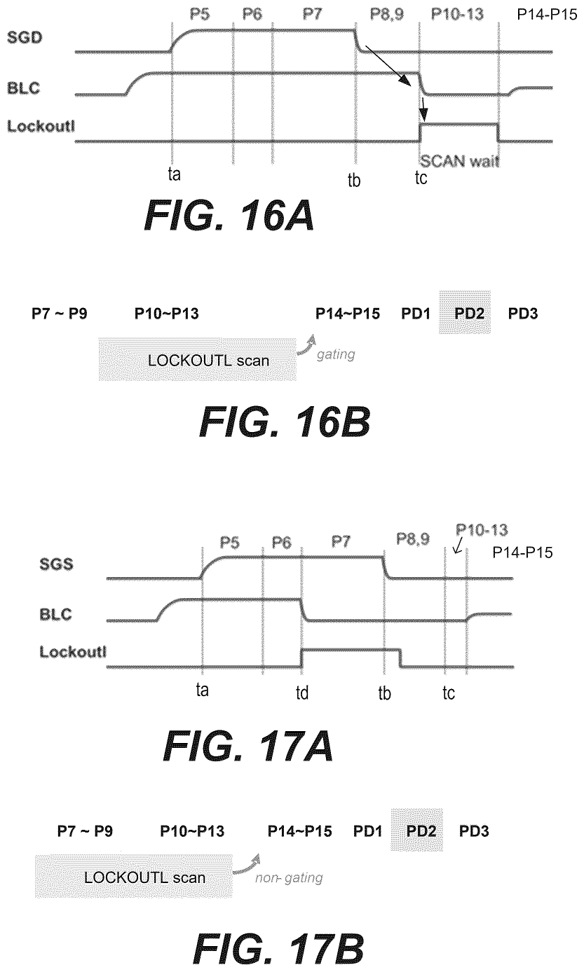

The voltage on the gate of the BLC transistor, in the case of NOP (e.g., memory cells are pre-charged in an order from the drain side to the source side), must wait for the voltage on the SGD to ramp down before the voltage on the BLC signal can be ramped down, as shown in FIG. 16A, This is because NOP relies on pre-charging memory cells from the drain side. Ramping down the BLC transistor clamps voltages on the bit lines and permits performing the lockoutL bit-scan. As a result, the lockoutL bit-scan can only start following ramping down of the BLC signal at P10 of the P_CLK. However, the lockoutL bit-scan logic may require time to execute, which may be more than allocated for P10-P13. Thus, as shown in FIG. 16B, the lockoutL bit-scan can result in gating application of VQPW to bit lines coupled to memory cells that passed the lockoutL bit-scan at P14, thereby delaying a programming operation.

In the case of ROP (e.g., memory cells are pre-charged in an order from the source side to the drain side), the BLC operation is decoupled from the memory pre-charging. Thus, the BLC does not need to wait for the SGS to ramp down before ramping down itself, as shown in FIG. 17A. Accordingly, to address the programming delay, an early lockoutL bit-scan mode can be utilized that shifts the start of the lockoutL bit-scan from P10 to P7. This is possible because the voltage on the gate of the BLC transistor can be ramped down earlier (e.g., at P7), as shown in FIG. 17A. This is possible in ROP because channel pre-charge is mainly from the source-side (e.g., SGS). Thus, the BLC transistor can be turned off earlier without degrading the channel pre-charge. By shifting the start of the lockoutL bit-scan to P7, the lockoutL bit-scan can be performed in the background of pre-charging during the P_CLK. This permits shorter time windows for P10-P13, after which the VQPW can be applied to appropriate bit lines at P14 (e.g., shown in FIG. 17B). The early lockoutL mode can reduce programming time by 1.3 μs for the TLC storage scheme, 10 μs for the MLC storage scheme, and 40 μs for finer storage schemes.

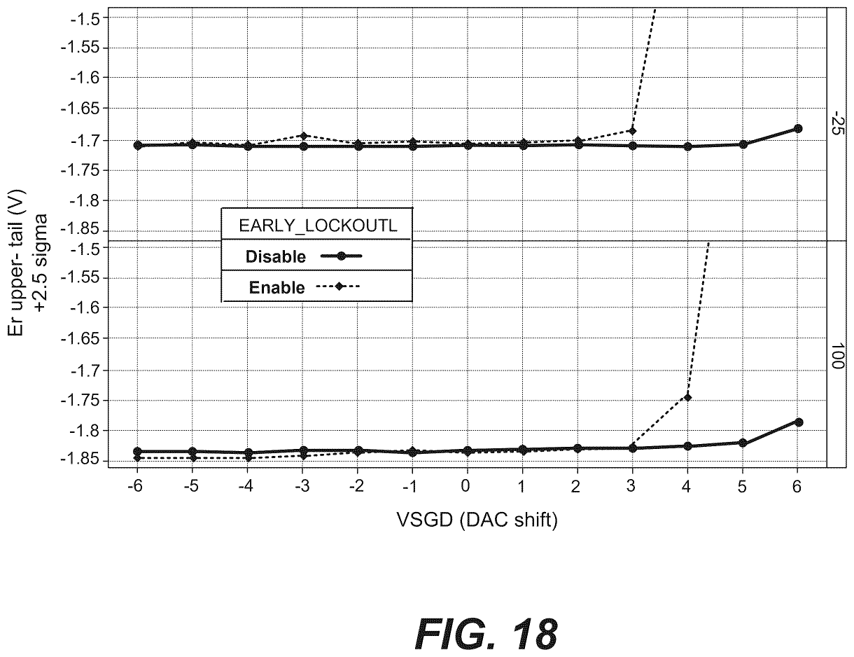

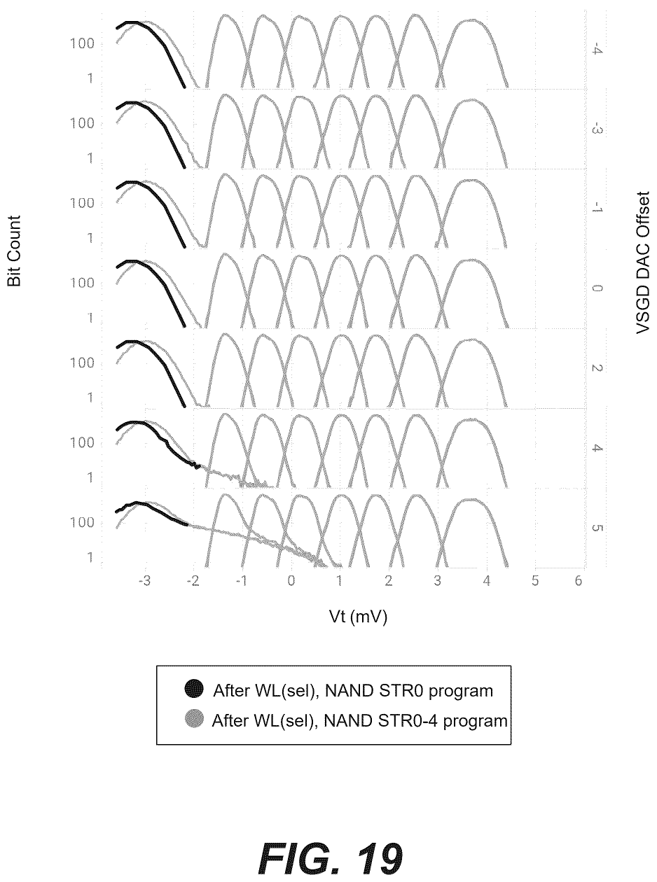

However, an issue regarding VSGD window loss can occur when using the early lockoutL bit-scan mode. Insufficient charging of inhibited bit lines and longer channel float times contribute to the VSGD window degradation (see, for example, FIG. 18 showing VSGD window loss as DAC shift as a function of upper tail of the erased state voltage distribution). Each NAND parameter has a digital-to-analog mapping table, and DAC may refer to the location in that table, representing the corresponding analog value applied to that parameter. The VSGD window loss induces an upper tail of the erased state distribution to deform (see, for example, FIG. 19 showing increasing upper tail deformation as a function of VSGD DAC offset). The upper tail deformation can result in program disturb, or unintentional programming of some of the memory cells.

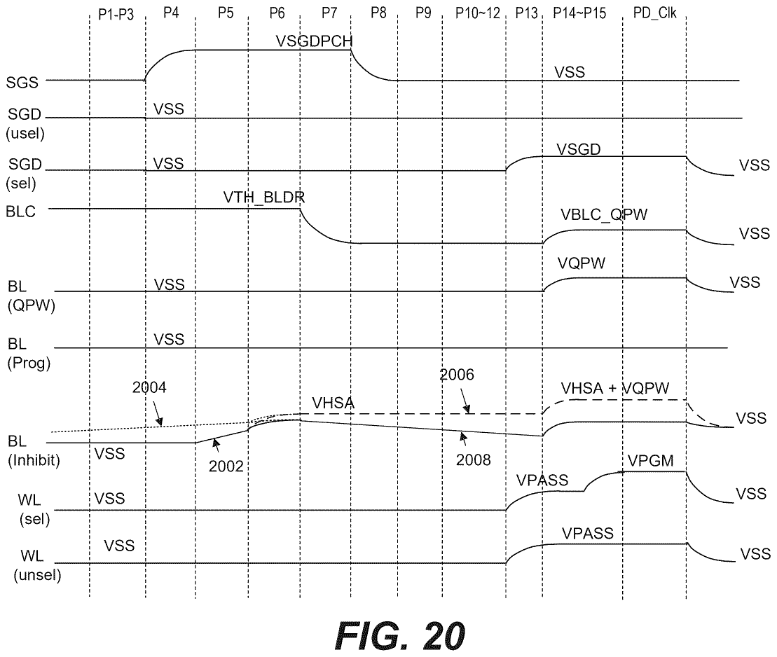

FIG. 20 illustrates voltages applied various components of a memory block during a program loop that performs a program-verify operation during pre-charging. FIG. 20 illustrates an example voltage signals applied in preparation for and during a lockoutL bit-scan performed using early lockoutL mode (e.g., lockoutL bit-scan started at time period P7 of the P_CLK, as described above in connection with FIG. 17A).

FIG. 20 depicts the following signals: SGS, SGD(sel), SGD (unsel), WL(sel), WL(unsel), BLC, BL(QPW), BL(Prog), BL(Inhibit). BL(Prog) is the voltage applied to bit lines connected to NAND strings having memory cells selected for programming. BL(Inhibit) is the voltage applied to bit lines connected to NAND strings that do not have any memory cells selected for programming. BL(QPW) is the voltage applied to bit lines connected to NAND strings having memory cells selected for slow programming. SGD (sel) is the voltage applied to the drain side select (SGD) line(s) for the region (e.g., regions WL0a, WL0b, WL0c and WL0d described above in connection with FIG. 7A) selected for programming. SGD (unsel) is the voltage applied to the SGD line(s) for the region not selected for programming. SGS is the voltage applied to the source side select (SGS) line(s). WL (sel) is the voltage on the data word line selected for programming, meaning that WL (sel) is connected to the memory cells selected for programming. WL (unsel) is the voltage on the unselected data word lines. BLC is the voltage applied to the gates of BLC transistors connected to the bit lines.

The sub-clocks of P1-P15 of FIG. 20 correspond to the P_CLK, during which selective word lines are ramped up (e.g., channel pre-charging) to VPGM and unselected word lines ramp to VPASS (e.g., steps 1304-1308 of FIG. 13). The PD_CLK correspond to programming of selected memory cells (e.g., step 1308 of FIG. 13) during program loop M of the program loops of steps 1304-1326. The sub-clocks of P10-P13 also correspond to a portion of a program-verify operation (e.g., step 1310 of FIG. 13) where memory cells selected for programming are verified to pass the VL voltage associated with a programmed data state (e.g., lockoutL bit-scan). For example, the sub-clocks P10-P13 may correspond to a bit-scan (e.g., lockoutL bit-scan). In examples, a prior bit-scan (e.g., lockoutH bit-scan) may be performed prior to the P_CLK, for example, during the RR_CLK. The sub-clocks of P13-P15 corresponds to boosting channels of unselected NAND strings (see step 1306 of FIG. 13) and applying a program voltage pulse to the selected data word line and selected memory cells (see step 1308 of FIG. 13) during loop M of the program loops of steps 1304-1326.

Prior to P1, the BLC signal may be at VTH_BLDR and all other signals depicted in FIG. 20 are at resting voltage of VSS (e.g., ground, 0 volts, or another appropriate resting voltage). At time P4, the signal SGS can be raised to VSGDPCH. Between P1 and P6, the BL(Inhibit) signal can be raised to the program inhibit voltage VHSA (e.g., approximately 3.5 volts). That is, the signal applied to bit lines couple to memory cells verified during a prior lockoutH bit-scan can be pre-charged to VHSA, Having the BLC signal at VTH_BLDR activates the BLC transistor and permits pre-charging of the bit lines coupled to memory cells to be inhibited from programming. In the case of Economic Verify To Program (ECOV2P) disable, the BL(Inhibit) signal can be ramped to VHSA starting at P5, as shown by signal 2002. In the case of ECOV2P enabled, the BL(Inhibit) signal can be ramped to VHSA at a time prior to initializing the P_CLK, as shown by signal 2004. In either case, the BL(Inhibit) signal may be ramped up following the prior lockoutH bit-scan that determines those memory cells that have been successfully programmed (e.g., threshold voltages have reached the VH voltage). At P7, the BLC signal can be ramped down to VSS and the SGS can be ramped down to VSS at P8, Ramping down the BLC signal clamps the voltages on the bit lines and permits starting the lockoutL bit-scan at P7. By starting the lockoutL bit-scan at P7, the scan can be completed prior to P13 and will not gate P14. The lockoutL bit-scan determines which memory cells, that are not inhibited from programming, have a threshold voltage above the VL voltage (e.g., steps 1512-1514 of FIG. 5).

At time P13, the SGD (sel) signal can be raised to VSGD (which is a voltage high enough to turn on a transistor for the selected gate, which may be approximately 3.5-6 v) and WI. (sel) and WL (unsel) can be boosted to VPASS (e.g., step 1306 of FIG. 13). At time P15, a program voltage pulse (VPGM) can be applied to WL (sel), which programs memory cells connected to BL(Prog), which are those memory cells selected for programming having a threshold voltage below the VL voltage. At time P14, the BLC signal is raised to VBLC_QPW, which is a voltage level high enough to turn on the BLC transistors to pre-charge the bit lines.

Thus at P14, BL(QPW) is pre-charged to VQPW. Raising the BL(QPW) signal to VQPW increases the voltage in the channels containing the memory cells for which slow programming is desired, thereby reducing the voltage difference between the VPGM and the channels and slowing the flow of electrons into the charge trapping materials of the memory cells being programmed when the VPGM is applied to the selected WL. As noted above, starting the lockoutL bit-scan at P7, can avoid gating the application of VBLC_QPW at P14, which likewise does not delay pre-charging the BL(QPW) signal. Thus, programming of memory cells can proceed without lockoutL bit-scan induced delays.

Ideally, when the VQPW signal is applied to the selected BL, the BL(Inhibit) signal ramps from VHSA to VSHA+VQPW, as shown by signal 2006. Thus, while memory cells connected to BL(Prog) can be programmed in response to the application of doses of VPGM, memory cells connected to BL(Inhibit) would be inhibited from programming due to the boosting of their channels. However, because the BLC signal is ramped down early (e.g., at P7 in this example) the channel will float (e.g., all bit lines will float) for a longer period of time that without early lockoutL bit-scan mode and the BL(Inhibit) signal may not be sufficiently charged to VHSA, as shown by signal 2008. That is, for example, where the BLC signal is ramped down at P10 (as shown in FIG. 16A), the BL(Prog), BL(Inhibit), and BL(QPW) each float between sub-clocks P10 to P14, at which the BLC signal is raised to VBLC_QPW. Yet, in the case of FIG. 20, the BL(Prog), BL(Inhibit), and BL(QPW) each float starting at P7, resulting in increased float time. The increased float time may result in insufficient VHSA charging on the BL(inhibit) signal resulting in a program disturb, which can contribute to VSGD window degradation.

An aspect of the present disclosure is related to flexibly allocating sub-clocks of a programming operation to at least one program-verify operation based on a sub-clock set for slow programming one or more memory cells. In examples, during the application of a programming pulse to a selected word line, a QPW voltage (VQPW) can be applied to bit lines coupled to one or more memory cells determined for slow programming. The bit lines can be pre-charged by the VQPW by turning on BLC transistors through application of VBLC_QPW to the gates of the BLC transistors. Timing of turning on the BLC transistors and pre-charging the bit lines can be set in control circuits (e.g., control circuitry 110, controller 122, and/or controller 150) by assigning the voltages to a sub-clock. Based on the assigned sub-clock, the control circuits can allocate one or more earlier sub-clocks to the at least one program-verify operation, which can be performed to determine which memory cells are to be programmed via slow programming (e.g., having threshold voltages between the VL and VH voltages). For example, a larger number of sub-blocks (e.g., more time) can be allocated to the at least one program-verify operation responsive to assigning the BLC activation to a later sub-clock. Compared to conventional approaches, which activate the BLC transistors prior to applying a programming pulse, examples herein can activate the BLC transistors after applying a programming pulse which permits flexible allocation of the sub-clocks while applying the programming pulse to the at least one program-verify operation (e.g., a lockoutL bit-scan).

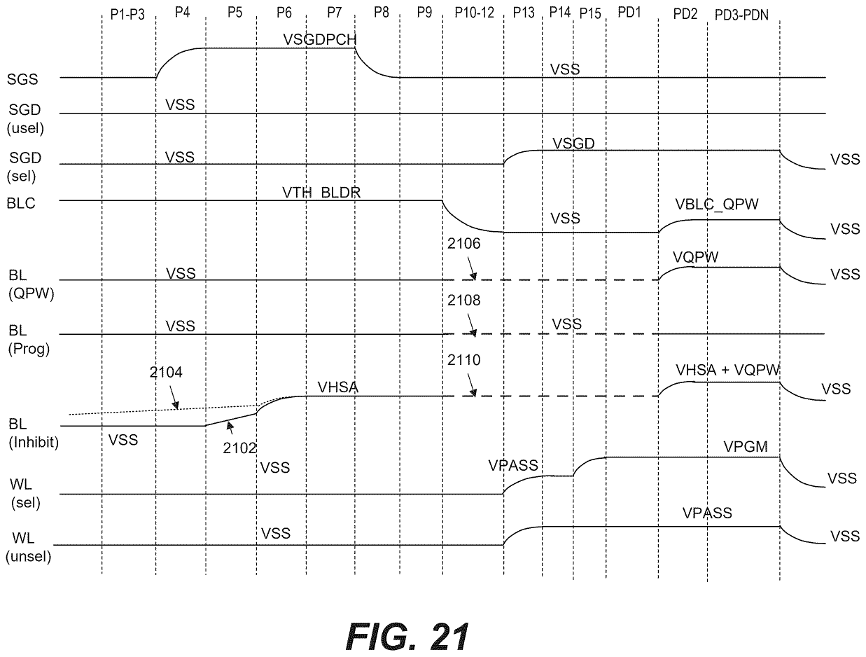

FIG. 21 illustrates voltages applied to various components of a memory block during an exemplary embodiment of a program loop with flexible allocation of a time window for at least one program-verify operation. FIG. 21 illustrates an example of voltage signals applied in preparation for and during a lockoutL bit-scan during a number of sub-clocks that are allocated dependent on a sub-clock set for slow programming (e.g., applying VQPW to bit lines).

FIG. 21 depicts the following signals: SGS, SGD (sel), SGD (unsel), WL (sel), WL (unsel), BLC, BL(QPW), BL(Prog), BL(Inhibit). BL(Prog) is the voltage applied to bit lines connected to NAND strings having memory cells selected for programming. BL(Inhibit) is the voltage applied to bit lines connected to NAND strings that do not have any memory cells selected for programming. BL(QPW) is the voltage applied to bit lines connected to NAND strings having memory cells selected for slow programming. SGD (sel) is the voltage applied to the drain side select (SGD) line(s) for the region (e.g., regions WL0a, WL0b, WL0c and WL0d described above in connection with FIG. 7A) selected for programming. SGD (unsel) is the voltage applied to the SGD line(s) for the region not selected for programming. SGS is the voltage applied to the source side select (SGS) line(s). WL (sel) is the voltage on the data word line selected for programming, meaning that WL (sel) is connected to the memory cells selected for programming. WL (unsel) is the voltage on the unselected data word lines. BLC is the voltage applied to the gates of BLC transistors connected to the bit lines.

The P_CLK in FIG. 21 is divided into sub-clocks P1-P15, during which selective word lines are ramped up (e.g., channel pre-charging) to VPGM and unselected word lines ramp to VPASS (e.g., steps 1304-1308 of FIG. 13). The PD_CLK, divided into PD1-PDN, corresponds to programming of selected memory cells (e.g., step 1308 of FIG. 13) during program loop M of the program loops of steps 1304-1326. In examples, a program-verify operation (e.g., lockoutH bit-scan) may be performed prior to the P_CLK, for example, during the RR_CLK, which determines one or more memory cells that are to be inhibited from programming (e.g., threshold voltages have passed the VH voltage). The sub-clocks of P13-P15 corresponds to boosting channels of unselected NAND strings (see step 1306 of FIG. 13) and applying a program voltage pulse to the selected data word line and selected memory cells (see step 1308 of FIG. 13) during loop M of the program loops of steps 1304-1326.

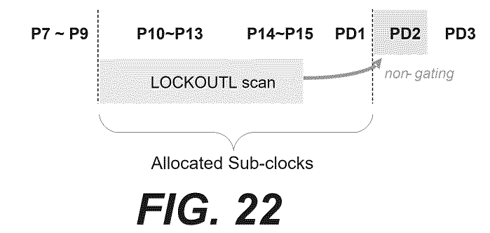

In the example of FIG. 21, sub-clock PD2 may be set for slow programming according to QPW techniques, as described above. Accordingly, in this example, the BLC signal is raised to VBLC_QPW at PD2, which turns on the BLC transistors and applies VQPW to the BL(QPW). In this case, sub-clocks of P10-PD1 may be allocated to a program-verify operation (e.g., step 1310 of FIG. 13) where memory cells selected for programming are verified to pass the VL voltage associated with a programmed data state (e.g., lockoutL bit-scan), as shown in FIG. 22. FIG. 22 depicts a schematic block timing diagram of the sub-clocks allocated to a program-verify operation (e.g., lockoutL bit-scan), which does not gate the start of slow programming set to sub-clock PD2. This allocation provides extra time (e.g., extra sub-clocks) for completing the program-verify operation, as shown in FIG. 22, compared to the approaches described in connection with FIGS. 16A-20. For example, the present example can provide for three sub-clocks (e.g., P14-PD1) in addition to P10-P13 for completing the program-verify operation.

However, slow programming may be set to other sub-clocks depending on the desired application. For example, in BiCS8 generation of flash memory, VBLC_QPW ramping can be set to P14, PD1, PD2, or PD3. Table 1 below shows sub-clock allocations for a program-verify operation and extra time allocated at various example VBLC_QPW ramp settings.

TABLE 1

| | Sub-clocks | |
|---|---|---|
| | allocated for | Extra time allocated for |
| | LOCKOUTL | LOCKOUTL bit-scan as |
| VBLC_QPW_RMP | bit-scan | compared to current POR |
| P14 | P10~P13 | 0 |
| PD1 | P10~P15 | P14 + P15 |
| PD2 | P10~PD1 | P14 + P15 + PD1 |
| PD3 | P10~PD2 | P14 + P15 + PD1 + PD2 |

Referring back to FIG. 21, prior to P1, the BLC signal may be at VTH_BLDR and all other signals depicted in FIG. 21 are at resting voltage of VSS. At P4, the signal SGS can be raised to VSGDPCH. Between P1 and P6, the BL(Inhibit) signal can be raised to the program inhibit voltage VHSA (e.g., approximately 3.5 volts). That is, the signal applied to bit lines couple to memory cells verified during a prior lockoutH bit-scan can be pre-charged to VHSA to inhibit programming. In the case of ECOV2P disable, the BL(Inhibit) signal can be ramped to VHSA starting at P5, as shown by signal 2102. In the case of ECOV2P enabled, the BL(Inhibit) signal can be ramped to VHSA at a time prior to initializing the P_CLK, as shown by signal 2104. In either case, the BL(Inhibit) signal may be ramped up following the prior lockoutH bit-scan that determines those memory cells that have been successfully programmed (e.g. threshold voltages have reached the VH voltage). At P8, the SGS signal can be ramped down to VSS and the BLC signal can be ramped down to VSS at P9, which permits the bit lines to float, shown in FIG. 21 as dashed lines 2106-2110. Ramping down the BLC signal clamps the voltages on the bit lines. The lockoutL bit-scan can then be initiated at P10 to determine which memory cells, that are not inhibited from programming, have a threshold voltage above the VL voltage (e.g., steps 1512-1514 of FIG. 5).

At P13, the SGD (sel) signal can be raised to VSGD and WL (sel) and WI (unsel) can be boosted to VPASS (e.g., step 1306 of FIG. 13). At P15, a program voltage pulse (VPGM) can be applied to WL (sel), which programs memory cells connected to BL(Prog), which are those memory cells selected for programming having a threshold voltage below the VL voltage. As discussed above, the BLC signal is raised to VBLC_QPW at PD2 to turn on the BLC transistors to pre-charge the bit lines, Thus at PD2, the BL(QPW) signal is ramped up to VQPW. As noted above, since the bit lines float starting at P10, the BL(Inhibit) signal has sufficient time to charge to VHSA, thereby avoiding the program disturb and VSGD window degradation described above. Additionally, by allocating extra sub-clocks to the lockoutL bit-scan by ramping up the BLC signal at PD2, the lockoutL bit-scan does not delay the pre-charging the BL(QPW) signal. Thus, programming of memory cells can proceed without lockoutL bit-scan induced delays.

Applying the VPQW to BL(QPW) at a delayed sub-clock (e.g., PD2 in this example) can be advantageous to ensure proper programming of the memory cells. For example, when the BL(Inhibit) signal is higher than the SGD (sel) signal, the BL(Inhibit) signal cuts off the SGD signal and inhibits programming to the coupled memory cells. When the SGD (sel) signal is cut off and the word lines (WL (sel) and WL (unsel) are ramp up, the channel is floating and programming is inhibited. Whereas, programming is desired for memory cells connected to BL(Prog) and BL(QPW). For the bit lines on which program is desired, the SGD needs to be conductive. Bit lines coupled to memory cells to be programmed (e.g., BL(Prog)) can be turned on successfully because the BL(Prog) is at VSS, and thus sufficient conduction on the SGD is easy to achieve due to the difference between the VSS and VSGD. However, because VQPW is higher than VSS, an issue having insufficient conduction may occur on BL(QPW). In some cases, there may not be sufficient conduction and the SGD may be cut off on the BL(QPW) or slightly cut off while the word lines are ramping to VPASS. In this case, because the SGD is cut off (or slightly cut off), the memory cells coupled to BL(QPW) may be inhibited from programming. Thus, to avoid such complications, the BL(QPW) may be held at VSS while the word lines ramp up to VPASS and ramped up to VQPW after ramping up the word lines, which can avoid accidental inhibit of programming.

Another aspect of the present disclosure is related to a flexible delay to at least one program-verify operation based on a sub-clock set for slow programming of one or more memory cells. In examples, during the application of a programming pulse to a selected word line, a VQPW can be applied to bit lines coupled to one or more memory cells determined for slow programming. The bit lines can be pre-charged by the VQPW by turning on BLC transistors through application of VBLC_QPW to the gates of the BLC transistors. Timing of turning on the BLC transistors and pre-charging the bit lines can be set in control circuits (e.g., control circuitry 110, controller 122, and/or controller 150) by assigning the voltages to a sub-clock. Based on the assigned sub-clock, the control circuits can delay the start of a program-verify operation, which may permit the BLC transistor to remain active for charging a program inhibit voltage on bit lines coupled to memory cells to be inhibited from programming. This functionality may reduce bit line floating time for improved VSGD window. Using the delayed start of a program-verify operation in tandem with the flexible allocation of sub-clocks for performing and completing the program-verify operation, as described above in connection with FIGS. 22-24, examples herein can avoid VSGD window degradation while permitting sufficient time to complete the operation.

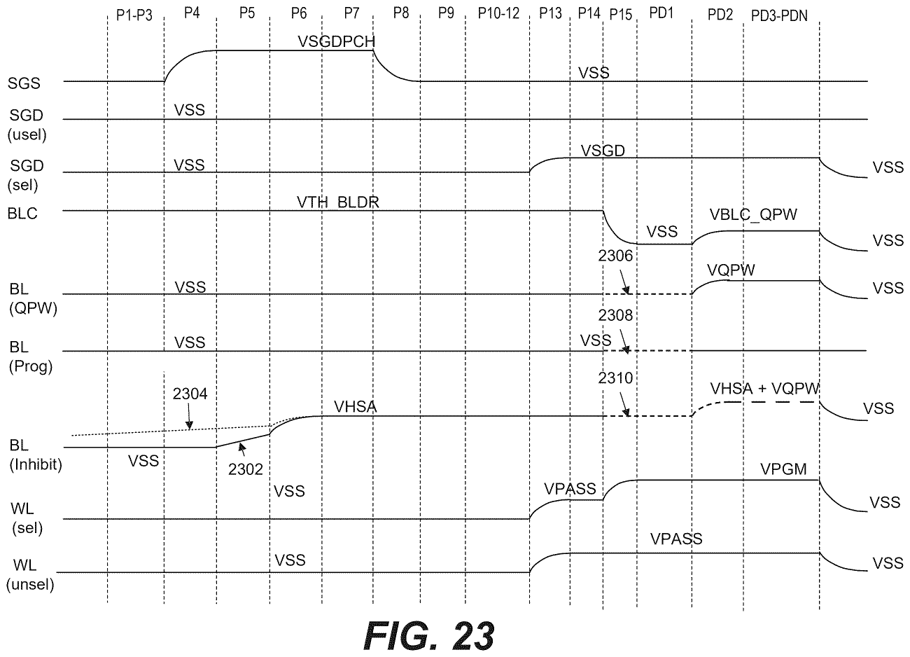

FIG. 23 illustrates voltages applied to various components of a memory block during an exemplary embodiment of a program loop with a delayed program-verify operation. FIG. 23 illustrates an example of voltage signals applied in preparation for and during a lockoutL bit-scan during a number of sub-clocks that are allocated dependent on a sub-clock set for slow programming (e.g., applying VQPW to bit lines).

FIG. 23 depicts the following signals: SGS, SGD (sel), SGD (unsel), WL (sel), WL (unsel), BLC, BL(QPW), BL(Prog), BL(Inhibit). BL(Prog) is the voltage applied to bit lines connected to NAND strings having memory cells selected for programming. BL(Inhibit) is the voltage applied to bit lines connected to NAND strings that do not have any memory cells selected for programming. BL(QPW) is the voltage applied to bit lines connected to NAND strings having memory cells selected for slow programming. SGD (sel) is the voltage applied to the drain side select (SGD) line(s) for the region (e.g., regions WL0a, WL0b, WL0c and WL0d described above in connection with FIG. 7A) selected for programming. SGD (unsel) is the voltage applied to the SGD line(s) for the region not selected for programming. SGS is the voltage applied to the source side select (SGS) line(s). WL (sel) is the voltage on the data word line selected for programming, meaning that WL (sel) is connected to the memory cells selected for programming. WL (unsel) is the voltage on the unselected data word lines. BLC is the voltage applied to the gates of BLC transistors connected to the bit lines.

The P_CLK in FIG. 23 is divided into sub-clocks P1-P15, during which selective word lines are ramped up (e.g., channel pre-charging) to VPGM and unselected word lines ramp to VPASS (e.g., steps 1304-1308 of FIG. 13). The PD_CLK, divided into PD1-PDN, corresponds to programming of selected memory cells (e.g., step 1308 of FIG. 13) during program loop M of the program loops of steps 1304-1326. In examples, a program-verify operation (e.g., lockoutH bit-scan) may be performed prior to the P_CLK, for example, during the RR_CLK, which determines one or more memory cells that are to be inhibited from programming (e.g., threshold voltages have passed the VH voltage). The sub-clocks of P13-P15 corresponds to boosting channels of unselected NAND strings (see step 1306 of FIG. 13) and applying a program voltage pulse to the selected data word line and selected memory cells (see step 1308 of FIG. 13) during loop M of the program loops of steps 1304-1326

Prior to P1, the BLC signal may be at VTH_BLDR and all other signals depicted in FIG. 21 are at resting voltage of VSS. At P4, the signal SGS can be raised to VSGDPCH. Between P1 and P6, the BL(Inhibit) signal can be raised to the program inhibit voltage VHSA. That is, the signal applied to bit lines couple to memory cells verified during a prior lockoutH bit-scan can be pre-charged to VHSA to inhibit programming. In the case of ECOV2P disable, the BL(Inhibit) signal can be ramped to VHSA starting at P5, as shown by signal 2302. In the case of ECOV2P enabled, the BL(Inhibit) signal can be ramped to VHSA at a time prior to initializing the P_CLK, as shown by signal 2304. In either case, the BL(Inhibit) signal may be ramped up following the prior lockoutH bit-scan that determines those memory cells that have been successfully programmed (e.g., threshold voltages have reached the VH voltage). At P8, the SGS can be ramped down to VSS.

The BLC signal may be ramped down from VTH_BLDR dependent on a sub-clock set for ramping up the BLC signal to VBLC_QPW. In the example of FIG. 23, sub-clock PD2 may be set for ramping up to VBLC_QPW, which turns on the BLC transistors and applies VQPW to the BL(QPW) at PD2. Because the BLC signal is ramped up at PD2, additional sub-clocks may be allocated to a program-verify operation (e.g., step 1310 of FIG. 13), as described above in connection with FIG. 21. That is, for example, additional sub-clocks may be allocated to a lockoutL bit-scan (e.g., step 1514 of FIG. 15). Since there are additional sub-clocks allocated for the lockoutL bit-scan, the start of the lockoutL bit-scan may be delayed, particularly where the lockoutL bit-scan does not require the entire allocated time. Because the lockoutL bit-scan can be delayed, the ramping down of BLC signal from VTH_BLDR can likewise be delayed to a later sub-clock.

In the example of FIG. 23, because the BLC signal is set to ramp up to VBLC_QPW at PD2, sub-clocks P15-PD1 can be allocated for the lockoutL bit-scan and the BLC signal can be ramped down to VSS at P15. This clamps the voltages on the bit lines and permits the bit lines to float, shown in FIG. 23 as dashed lines 2306-2310. The lockoutL bit-scan can then be initiated at P15 to determine which memory cells, that are not inhibited from programming, have a threshold voltage above the VL voltage (e.g., steps 1512-1514 of FIG. 5). Since the bit lines float starting at P15, the BL(Inhibit) signal has sufficient time to charge to VHSA, thereby avoiding the program disturb and VSGD window degradation described above. Additionally, by allocating extra sub-clocks to the lockoutL bit-scan by ramping up the BLC signal at PD2, the lockoutL bit-scan does not delay the pre-charging the BL(QPW) signal. Thus, programming of memory cells can proceed without lockoutL bit-scan induced delays.

At P13, the SGD (sel) signal can be raised to VSGD and WL (sel) and WL (unsel) can be boosted to VPASS (e.g., step 1306 of FIG. 13). At P15, a program voltage pulse (VPGM) can be applied to WL (sel), which programs memory cells connected to BL(Prog), which are those memory cells selected for programming having a threshold voltage below the VL voltage. The BLC signal, in the example of FIG. 23, is raised to VBLC_QPW at PD2 to turn on the BLC transistors to pre-charge the bit lines. Thus at PD2, the BL(QPW) signal is ramped up to VQPW.

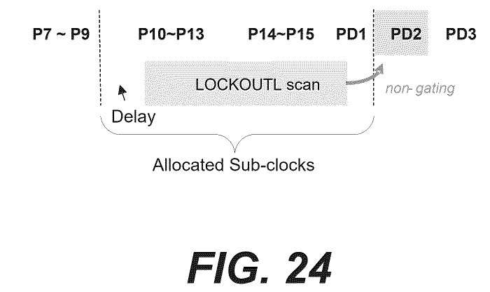

FIG. 24 depicts a schematic block timing diagram of the sub-clocks allocated to a program-verify operation with a delayed start. FIG. 24, in various examples, shows sub-clocks allocated to a bit-scan of the program-verify operation, such as a lockoutL bit-scan. As shown in FIG. 24, the lockoutL bit-scan can be delayed within the allocated sub-blocks without gating the start of slow programming set to sub-clock PD2.

In the above examples, PD2 is set as the sub-clock at which the BLC signal is ramped to VBLC_QPW. However, slow programming may be set to other sub-clocks depending on the desired application. Table 2 below shows BLC falling (e.g., ramping down from VTH_BLDR), sub-clock allocations for a lockoutL bit-scan, and extra time allocated at various example VBLC_QPW ramp settings.

TABLE 2

| | | Sub-clocks | |
|---|---|---|---|
| | | allocated for | Extra time allocated for |
| | BLC | LOCKOUTL | LOCKOUTL bit-scan as |
| VBLC_QPW_RMP | falling | bit-scan | compared to current POR |
| P14 | P10 | P10~P13 | 0 |
| PD1 | P13 | P13~P15 | P14 + P15 − P10 − |
| | | | P11 − P12 |
| PD2 | P15 | P15~PD1 | P15 + PD1 − P10 − |
| | | | P11 − P12 − P13 |
| PD3 | PD1 | PD1~PD2 | PD1 + PD2 − P10 − |
| | | | P11 − P12 − P13 |

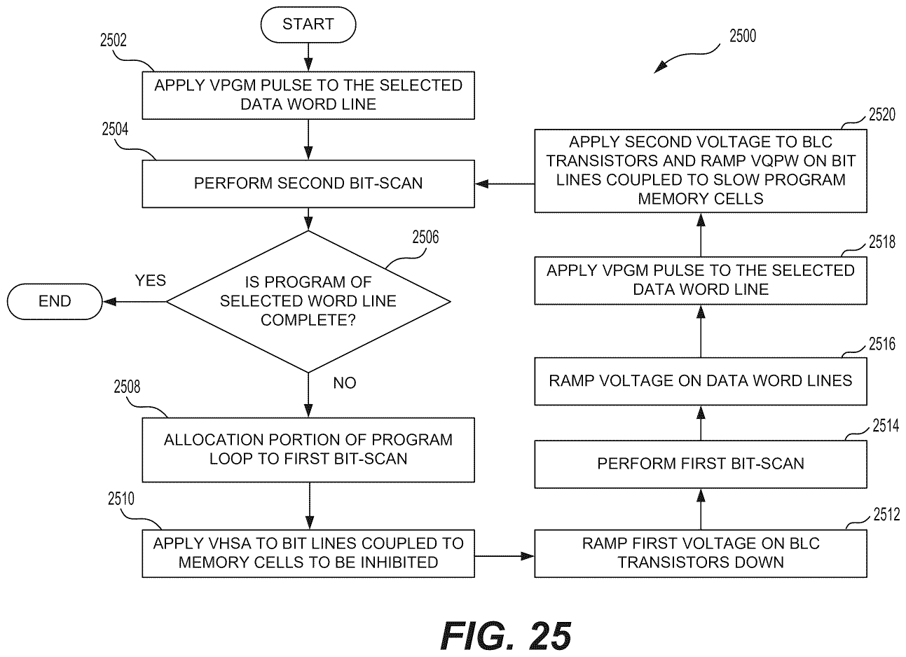

FIG. 25 is a flow chart 2500 that depicts examples steps of programming the memory cells of a selected word line to multiple bits per memory cell in a plurality of program loops. These steps could be performed by the controller, a processor or processing device or any other circuitry, executing instructions stored in memory, and/or other circuitry described herein that is specifically configured/programmed to execute the following steps. For example, control circuitry 110, controller 122, and/or control circuit 150 may be utilized to perform the steps of flow chart 2500.

At step 2502, a VPGM pulse is applied to a selected data word line to program one or more non-inhibited memory cells connected to the selected word line. At step 2504, a second bit-scan is performed. The second bit-scan may include verifying results of a sensing operation (e.g., verifying one or more pulses) to check if the threshold voltages Vth of the memory cells connected to the selected data word line exceed the verify high (VH) voltages associated with the intended data states of those memory cells. The second bit-scan may determine which memory cells are to be inhibited from further programming because their threshold voltages have passed the VH voltage associated with the intended data states. The second bit-scan may be an example lockoutH scan.

At decision step 2506, it is determined if programming of the selected data word line is completed, i.e., has programming to all data states been completed. If the answer at decision step 2506 is “yes,” then the programming operation is completed. If the answer at decision step 2506 is “no,” then the process continues through a plurality of program loops until either programming is completed or fails.

At step 2508, a portion of the program loop can be allocated for a first bit-scan based on a portion of the program loop allocated for initiating slow programming. For example, at step 2508, a setting for ramping up a voltage applied to gates of BLC transistors to VBLC_QPW may be checked and a portion (e.g., a sub-clock) of the program loop can be allocated to the first bit-scan dependent on the setting. In examples, the allocated portion may include allocating additional portions (e.g., sub-clocks) to the operation. As an illustrative example, sub-clocks P14-PD1 can be allocated to the first bit-scan where the slow programming is initiated at sub-clock PD2, as described above in connection with FIG. 21. In examples, step 2508 may also include setting a portion of the program loop at which the first bit-scan can be started dependent on the setting for initiating the slow programming (e.g., delaying the start as described above in connection with FIG. 23).

At step 2510, a program inhibit voltage (VHSA) is applied to bit lines coupled to those memory cells to be inhibited from further programming as determined by the second bit-scan (step 2504) while a first voltage (e.g., VTH_BLDR) is applied to gates of BLC transistor connected to the bit lines. At step 2512, the first voltage is ramped down to VSS (or ground). The first voltage may be ramped down depending on the portion of the program loop set for the start of the first bit-scan. In one instance, step 2512 may be performed at sub-clock P10 as described in connection with FIG. 21. In another example, step 2512 may be performed at any sub-clock between P10 and the sub-clock set for starting the slow programming, as described in connection with FIG. 23.

At step 2514, the first bit-scan is performed during the allocated portion of the program loop. The first bit-scan may include verifying results of the sensing operation to check if the threshold voltages Vth of the memory cells connected to the selected data word line exceed the verify low (VL) voltages associated with the intended data states of those memory cells. The first bit-scan may determine which memory cells are to be programmed slowly because their threshold voltages have passed the VL voltage associated with the intended data states but are below the VH voltage. The first bit-scan may be an example of lockoutL bit-scan.

At step 2516, the channels of the data word lines are boosted by applying a pass voltage (VPASS). The VPASS may be applied to both selected and unselected data word lines. In some examples, as shown in FIG. 21, the channels of the data word lines may be boosted after the first voltage is ramped down. In other examples, as shown in FIG. 23, the channels of the data word lines may be boosted before the first voltage is ramped down (e.g., step 2516 may be performed prior to steps 2512 and 2514). At step 2518, a VPGM pulse for the next program loop is applied to the selected data word line to program any non-inhibited memory cells, including memory cells to be programmed slowly, connected to the selected data word line.

At step 2520, a second voltage is applied to gates of the BLC transistors (e.g., VBLC_QPW), which turns on the BLC transistors and applies VQPW to the bit lines coupled to those memory cells determined for slow programming (e.g., step 2514). The VQPW increases the voltage in the channels containing the memory cells for which slow programming is desired, thereby reducing the voltage difference between the programming pulse VPGM and the channels and slowing the flow of electrons into the charge trapping materials of the memory cells being programmed.

Each of the processes, methods, and flow charts described in the preceding sections may be embodied in, and fully or partially automated by, code components executed by one or more controllers or memory devices. The methods, processes, and flow charts described herein are also not limited to any particular sequence, and the blocks or steps relating thereto can be performed in other sequences that are appropriate, or may be performed in parallel, or in some other manner. Blocks or steps may be added to or removed from the disclosed examples. For example, the various features and processes described in the various embodiments disclosed above may be used independently of one another, or may be combined in various ways. The disclosed processes, methods, and flow charts may thusly have steps or blocks added to or removed therefrom due to combining the various examples disclosed above.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that includes the element.

The terms “a,” “an,” and “the” also refer to “one or more” unless expressly specified otherwise. By way of example, “a processor” programmed to perform various functions refers to one processor programmed to perform each and every function or more than one processor collectively programmed to perform each of the various functions. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A method for performing a program-verify operation of a memory device, comprising steps of:
preparing a memory block that includes a plurality of memory cells that are connected to a plurality of data word lines;
performing a first operation of the program-verify operation to verify a threshold voltage of one or more memory cells connected to a selected data word line of the plurality of data word lines is above a verify low voltage; and
during the first operation, applying a programming voltage to the selected data word line.

2. The method as set forth in claim 1, wherein the first operation is a lockout low bit-scan.

3. The method as set forth in claim 1, wherein performing the first operation further includes steps of:
applying a verify low voltage to the selected data word lines; and
verifying the programming of the one or more memory cells connected to the selected data word line based on the verify low voltage.

4. The method as set forth in claim 1, further comprising:
performing the first operation after ramping down a voltage on a gate of a bit line clamp (BLC) transistor connected to a bit line coupled to the one or more memory cells; and
applying a VBLC_QPW to the gate of the BLC transistor after the first operation is completed.

5. The method as set forth in claim 4, wherein a time window allocated to the first operation is defined based on setting a time at which the VBLC_QPW is applied to the gate of the BLC transistor.

6. The method as set forth in claim 4, wherein the first operation is started based on setting a time at which the VBLC_QPW is applied to the gate of the BLC transistor.

7. The method as set forth in claim 1, wherein performing a first operation comprises:
determining the threshold voltage of the one or more memory cells is above the verify low voltage; and
applying a quick pass write voltage to a bit line coupled to the one or more memory cells based on the determination.

8. The method as set forth in claim 6, wherein the quick pass write voltage is applied to the bit line coupled to the one or more memory cells after the programming voltage is applied to the selected data word line.

9. The method as set forth in claim 1, further comprising:
applying a boosting voltage to one or more of unselected data word lines and the selected data word line; and
starting the first operation after applying the boosting voltage.

10. The method as set forth in claim 1, further comprising:
prior to performing the first operation,
performing a second operation to verify a threshold voltage of at least one memory cell connected to the selected data word line of the plurality of data word lines is above a verify high voltage; and
applying a program inhibit voltage to a bit line coupled to the at least one memory cell.

11. A memory device, comprising:
a memory block that includes a plurality of memory cells that are arranged in a plurality of data word lines; and
circuitry that is configured to conduct a first operation of a program-verify operation to verify a threshold voltage of one or more memory cells connected to a selected data word line of the plurality of data word lines is above a verify low voltage and, during the first operation, apply a programming voltage to the selected data word line.

12. The memory device as set forth in claim 11, wherein performing the first operation further includes steps of:
applying a verify compare voltage to the first set of data word lines; and
verifying the programming of one or more memory cells connected to a selected data word line based on the verify compare voltage.

13. The memory device as set forth in claim 11, wherein the circuitry is further configured to:
perform the first operation after ramping down a voltage on a gate of a bit line clamp (BLC) transistor connected to a bit line coupled to the one or more memory cells; and
apply a VBLC_QPW to the gate of the BLC transistor after the first operation is completed.

14. The memory device as set forth in claim 13, wherein a time window allocated to the first operation is defined based on setting a time at which the VBLC_QPW is applied to the gate of the BLC transistor.

15. The memory device as set forth in claim 13, wherein the first operation is started based on setting a time at which the VBLC_QPW is applied to the gate of the BLC transistor.

16. The memory device as set forth in claim 11, wherein performing the first operation comprises:
determining the threshold voltage of the one or more memory cells is above the verify low voltage; and
applying a quick pass write voltage to a bit line coupled to the one or more memory cells based on the determination.

17. The memory device as set forth in claim 14, wherein the quick pass write voltage is applied to the bit line coupled to the one or more memory cells after the programming voltage is applied to the selected data word line.

18. The memory device as set forth in claim 11, wherein the circuitry is further configured to:
prior to performing the first operation,
perform a second operation to verify a threshold voltage of at least one memory cell connected to the selected data word line of the plurality of data word lines is above a verify high voltage; and
apply a program inhibit voltage to a bit line coupled to the at least one memory cell.

19. An apparatus, comprising:
a memory block that includes a plurality of memory cells that are arranged in a plurality of word lines and in a plurality of bit lines, wherein the bit lines comprise bit line claim (BLC) transistors;
a controller that is configured to program one or more memory cells connected to a selected word line in a programming operation and allocate a portion of the programming operation to a first operation based on a setting that defines when a voltage is applied to the BLC transistors, the programming operation including:
during the program-verify operation:
verifying a threshold voltage of one or more memory cells connected to a selected data word line of the plurality of data word lines is above a verify low voltage, and
applying a programming voltage to the selected data word line.

20. The apparatus as set forth in claim 19, wherein the programming operation further includes:
performing the first operation after ramping down the voltage on the BLC transistors; and
applying a VBLC_QPW to the BLC transistor after the first operation is completed.
